(19) United States
(12) Patent Application Publication
(10) Pub. No.: US 2026/0259156 A1
(43) Pub. Date: Sep. 3, 2026

(54) DYNAMIC SWITCHING OF A DETECTOR SWITCH MATRIX

(71) Applicant: ASML Netherlands B.V., Veldhoven (NL)

(72) Inventors: Jan BEX, Pelt (BE); Harald Gert Helmut NEUBAUER, Erlangen (DE); Matthias OBERST, Nürnberg (DE); Bernd Michael VOLLMER, Dresden (DE); Hindrik Willem MOOK, The Hague (NL); Utku ULUDAG, Delft (NL)

(73) Assignee: ASML Netherlands B.V., Veldhoven (NL)

(21) Appl. No.: 18/876,017

(22) PCT Filed: Jul. 24, 2023
(86) PCT No.: PCT/EP2023/070486

§ 371 Date: Dec. 17, 2024

(30) Foreign Application Priority Data
Aug. 8, 2022 (EP) 22189246.6

(51) Int. Cl. G01N 23/2251

(52) U.S. Cl. CPC G01N 23/2251; G01N 2223/507

(57) ABSTRACT

A charged particle detector includes an array of sensing elements that may be selectively grouped with each other by a switch matrix. The sensing elements may be grouped in a shape and location that corresponds to an expected shape and location of beam spot to be detected.

During a detection process, the grouping of sensing elements may be updated in real time.

Updating may include both adding peripheral sensing elements to the group, as well as removing peripheral sensing elements from the group. A sensing element may be added if it is determined to be receiving sufficient irradiation from the beam spot. A sensing element may be removed if it is determined to not be receiving sufficient irradiation from the beam spot. The determination may be made by a thresholding circuit located within each sensing element.

### CROSS-REFERENCE TO RELATED APPLICATIONS

This application claims priority of EP application 22189246.6 which was filed on Aug. 8, 2022 and which is incorporated herein in its entirety by reference.

### TECHNICAL FIELD

The description herein relates to detectors, and more particularly, to detectors that may be applicable to charged particle detection.

### BACKGROUND

Detectors may be used for sensing physically observable phenomena. For example, some charged particle beam tools, such as electron microscopes, comprise detectors that receive charged particles projected from a sample and that output detection signals. Detection signals may be used to reconstruct images of sample structures under inspection and may be used, for example, to reveal defects in the sample. Detection of defects in a sample is increasingly important in the manufacturing of semiconductor devices, which may include large numbers of densely packed, miniaturized integrated circuit (IC) components. Inspection systems may be provided for this purpose. For example, a charged particle (e.g., electron) beam microscope, such as a scanning electron microscope (SEM) or a transmission electron microscope (TEM), capable of resolution down to less than a nanometer, serves as a practical tool for inspecting IC components having a feature size that is sub-100 nanometers. Electron microscopes work by irradiating a sample with an electron beam, then detecting secondary or backscattered electrons (or other types of secondary particles) on a detector. The secondary particles may form one or more beam spots on the detector surface.

Some detectors include a pixelated array of multiple sensing elements. A pixelated array can be useful because it may allow a detector configuration to be adapted to the size and shape of beam spots formed on the detector. When multiple primary beams are used, with multiple secondary beams incident on the detector, a pixelated array may be segregated into different regions of the detector associated with different beam spots. Each region may form its own group of sensing elements (pixels) that are used to detect individual beam spots.

To form detection groups for the different beam spots, a typical process includes two steps. First, a picture of the detector surface is acquired. In a so-called “picture mode,” output of each of the sensing elements of the pixelated array may be read, and an image that represents a projection pattern of secondary beam spots on the detector surface may be formed. That is, an image of the entire detector surface is generated. Based on this image, a border of each beam spot may be estimated, and a group of sensing elements may be chosen such that a boundary of the group approximates the border of the beam spot. This chosen group of sensing elements may be used later to detect the beam spot during a “beam mode.”

### SUMMARY

Some embodiments of the present disclosure provide a charged particle detector comprising. The charged particle detector may comprise: a substrate; a plurality of switching elements formed on the substrate and configured to form a switching matrix, the switching matrix having a plurality of inputs, each of the inputs being configured to connect to a different one of a plurality of sensing elements, each of the sensing elements being configured to generate a signal in response to a charged particle impacting the sensing element, the switching matrix being configured to combine a grouping of signals generated from a grouping of sensing elements, the grouping of sensing elements being associated with a charged particle beam spot formed on the charged particle detector; and a plurality of threshold circuits, each of the threshold circuits being coupled to a different one of the plurality of sensing elements, wherein a first threshold circuit of the plurality of threshold circuits is coupled to a first sensing element of the plurality of sensing elements and is configured to actuate a first switching element of the switch matrix based on a comparison of a signal level of the first sensing element to a threshold. The first sensing element may be configured to be identified as a candidate for one of being added to the grouping of sensing elements and being removed from the grouping of sensing elements based on proximity of the first sensing element to a boundary of the grouping of sensing elements. The first threshold circuit may be configured to initiate the comparison in response to the first sensing element being identified as the candidate.

Some embodiments of the present disclosure provide a non-transitory computer-readable medium that stores a set of instructions that is executable by at least one processor of an apparatus to cause the apparatus to perform a method. The method may comprise: receiving, by sensing elements of an electron detector, electrons from multiple secondary electron beams emitted by a sample in response to a plurality of primary beams of the multi-beam SEM interacting with the sample, each of the secondary beams being associated with a different one of the plurality of primary beams; based on the received electrons, coupling a first grouping of the sensing elements of the electron detector corresponding to a first beam spot of one of the secondary electron beams. The method may further comprise: coupling a first sensing element to the first grouping in response to a first detected charge at the first sensing element exceeding a first threshold; wherein coupling the first sensing element to the first grouping enables charge to be passed from the first sensing element to a signal readout path of the first grouping. Alternatively or additionally, the method may further comprise decoupling a second sensing element from the first grouping in response to a second detected charge at the second sensing element falling below a second threshold, wherein decoupling the second sensing element from the first grouping prevents charge from being passed from the second sensing element to the signal readout path of the first grouping.

### BRIEF DESCRIPTION OF DRAWINGS

FIG. 1 is a schematic diagram illustrating an exemplary charged-particle beam inspection system, consistent with embodiments of the present disclosure.

FIG. 2 is a schematic diagram illustrating an exemplary multi-beam beam tool, consistent with embodiments of the present disclosure that can be a part of the exemplary charged-particle beam inspection system of FIG. 1.

FIG. 3A is a schematic representation of an exemplary structure of a detector, consistent with embodiments of the present disclosure.

FIG. 3B is a diagram illustrating an exemplary surface of a detector array, consistent with embodiments of the present disclosure.

FIG. 4 is a diagram illustrating an exemplary detector array with switching elements, consistent with embodiments of the present disclosure.

FIG. 5 is a diagram illustrating a cross-sectional view of a layer structure of a detector, consistent with embodiments of the present disclosure.

FIG. 6 is a diagram illustrating a cross-sectional view of a sensing element of a detector, consistent with embodiments of the present disclosure.

FIG. 7 is a diagram representing an exemplary section arrangement of a detector, consistent with embodiments of the present disclosure.

FIG. 8 is a diagram representing another exemplary section arrangement of a detector, consistent with embodiments of the present disclosure.

FIG. 9 is a diagram representing a detection system, consistent with embodiments of the present disclosure.

FIG. 10A is a diagram illustrating a beam spot and sensing element group boundary, consistent with embodiments of the present disclosure.

FIG. 10B is a diagram illustrating a plurality of beam spots and a plurality of sensing element group boundaries, consistent with embodiments of the present disclosure.

FIGS. 11A-B are diagrams illustrating a sensing element circuit architecture, consistent with embodiments of the present disclosure.

FIG. 11C is a diagram illustrating a sensing element circuit architecture, consistent with embodiments of the present disclosure.

FIGS. 12A-F illustrate an exemplary process for updating a sensing element group, consistent with embodiments of the present disclosure.

FIG. 13 is a flowchart of an exemplary method of updating a sensing element group, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing charged-particle beams (e.g., electron beams), the disclosure is not so limited. Other types of charged particle beams may be similarly applied. Furthermore, other imaging systems may be used, such as optical imaging, photodetection, x-ray detection, or the like.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (“SCPM”). For example, an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur.

The working principle of a SEM is similar to a camera. A camera takes a picture by receiving and recording intensity of light reflected or emitted from people or objects. A SEM takes a “picture” by receiving and recording energies or quantities of electrons reflected or emitted from the structures of the wafer. Before taking such a “picture,” an electron beam may be projected onto the structures, and when the electrons are reflected or emitted (“exiting”) from the structures (e.g., from the wafer surface, from the structures underneath the wafer surface, or both), a detector of the SEM may receive and record the energies or quantities of those electrons to generate an inspection image. To take such a “picture,” the electron beam may scan through the wafer (e.g., in a line-by-line or zig-zag manner), and the detector may receive exiting electrons coming from a region under electron-beam projection (referred to as a “beam spot”). The detector may receive and record exiting electrons from each beam spot one at a time and join the information recorded for all the beam spots to generate the inspection image. Some SEMs use a single electron beam (referred to as a “single-beam SEM”) to take a single “picture” to generate the inspection image, while some SEMs use multiple electron beams (referred to as a “multi-beam SEM”) to take multiple “sub-pictures” of the wafer in parallel and stitch them together to generate the inspection image. By using multiple electron beams, the SEM may provide more electron beams onto the structures for obtaining these multiple “sub-pictures,” resulting in more electrons exiting from the structures. Accordingly, the detector may receive more exiting electrons simultaneously and generate inspection images of the structures of the wafer with higher efficiency and faster speed.

Exiting electrons received by the detector of the SEM may cause the detector to generate electrical signals (e.g., current signals or voltage signals) commensurate to the energy of the exiting electrons and the intensity of the electron beam. For example, the amplitudes of the electrical signals may be commensurate to the charges of the received exiting electrons. The detector may output the electrical signals to an image processor, and the image processor may process the electrical signals to form the image of structures of the wafer. A multi-beam SEM system uses multiple electron beams for inspection, and a detector of the multi-beam SEM system may have multiple sections to receive them. Each section may have multiple sensing elements and may be used to form a “picture” of a sub-region of the wafer. The “picture” generated based on signals from each section of the detector may be merged to form a complete picture of the inspected wafer.

The sections of the detector may be communicatively interconnected. Each section of the detector may have corresponding signal processing circuits for processing the electrical signals generated by the detector. When an electron beam impinges on a section, its signal processing circuits may be activated for signal processing. When an electron beam impinges on multiple adjacent sections, their signal processing circuits may be activated in a coordinated way for signal processing. When no electron beam impinges on the section, its signal processing circuits may be deactivated or may stand idle. When an electron beam impinges on a malfunctioning section, signal processing circuits of its adjacent section may be activated for signal processing. By such an interconnecting-section design, the detector of the SEM may provide flexibilities and malfunction tolerance to signal processing of the detector.

In addition to activating sensing elements at the section-level, individual sensing elements may be coupled to each other using an array of switching elements in a switch matrix of the detector. By coupling individual sensing elements, a detector may functionally group a plurality of sensing elements together so that the group of sensing elements matches the shape and location of a beam spot on the detector. This may be achieved by first operating in a picture mode to determine an appropriate grouping of sensing elements, and then coupling the chosen sensing elements together for normal use during a beam mode.

In picture mode, output of each of the sensing elements in a detector array may be read, and an image that represents a projection pattern of secondary beam spots on the detector surface may be formed (e.g., a secondary electron beam spot image). That is, an image of the entire detector surface is generated. Based on this image, a border of each beam spot may be estimated, and a group of sensing elements may be chosen such that a boundary of the group approximates the border of the beam spot. This chosen group of sensing elements may be used later to detect the beam spot during a beam mode.

In a beam mode during, e.g., an inspection process, sensing elements located within the determined boundary may be grouped together, and their outputs may be merged with each other to acquire intensity of the one secondary beam spot associated with the boundary. Sensing elements outside the boundary may be deactivated to reduce parasitic parameters, or unwanted electromagnetic effects from circuit components. Thus, the picture mode may be useful for determining a boundary within which a desired grouping of sensing elements may be used during an inspection process in the beam mode. The boundary ideally includes every sensing element that is receiving a portion of the beam spot and excludes every sensing element that does not. Cross-talk occurs when electrons from different beam spots land in the same group of sensing elements and should be avoided.

The detector has many performance indicators. One indicator is the “pixel rate,” which is the rate at which pixels of the inspection image are generated. The pixel rate may indicate the digital data processing bandwidth in a digital system, and the maximum pixel rate of a detector may indicate its maximum digital data processing speed. Another indicator is the “analog signal bandwidth,” which is the frequency range between the lowest and highest attainable frequency of analog signals. High-frequency analog signals may reflect “details” of the inspected structures. The analog signal bandwidth indicates the detection capability of the detector and fineness of the inspection results, which is a different performance indicator from the pixel rate. For example, even if the pixel rate is high, the inspection image may still be blurred if the analog signal bandwidth is low, because some details of the structures may be lost due to the low analog signal bandwidth and may not be reflected in the inspection image.

The pixel rate and analog signal bandwidth are prone to parasitic parameters. The parasitic parameters may include parasitic capacitance (e.g., stray capacitance), parasitic resistance, or parasitic inductance. The parasitic parameters may be incurred even when some components are not operating. The parasitic parameters may alter the designed specification of the components, and may cause adverse effects to the performance of the detector, such as suppressing signal dynamics and reducing the pixel rate. For example, stray capacitance may resist the movement of electric charges. Parasitic resistance may increase internal detection signal loss. Parasitic inductance may resist the flow of a dynamic electric current. In addition, the parasitic parameters may introduce noise and interference to the inspection image. Further discussion of parasitic parameters as they relate to detector architecture may be found in International Publication No. WO 2021/239754 A1, the content of which is incorporated herein by reference in its entirety.

The pixel rate and analog signal bandwidth may have significant impacts on other performance indicators of the detector, such as a signal-to-noise (“SNR”) ratio or performance capacity (e.g., maximum inspection speed or maximum inspection throughput) of the detector. For increasing the pixel rate and analog signal bandwidth, a detector may be designed to shorten the distance of the electrical connections between individual sensing elements and their signal processing circuits, which may suppress the generation of parasitic parameters (e.g., series resistance, parasitic capacitance, or series inductance). Alternatively, architectures of the signal processing circuits may be enhanced or redesigned for the detector to be less sensitive to the parasitic parameters.

It is desirable for a sensing element group to match a beam spot as closely as possible. If a sensing element outside the chosen group receives a portion of the beam spot, that portion will not be detected. However, each sensing element that is added to the group will introduce unwanted parasitic parameters. Additionally, increasing a size of a sensing element group increases the risk of cross-talk from neighboring beam spots. Therefore, one cannot simply define a sensing element group to be much larger than the beam spot without incurring a penalty.

One issue that contributes to a mismatch between the beam spot and the group of sensing elements assigned to it is a shift of the beam spot over time. The size, shape, or location of a beam spot may change during a charged particle beam process so that an original grouping boundary no longer matches the existing beam spot. Sensing elements that do not belong to the group may be receiving a portion of the beam spot without passing any signal on to a signal readout path of the detector. Additionally, sensing elements that are in the group may not be receiving any portion of the beam spot. These sensing elements add parasitic parameters to the system without contributing anything of use.

It would be beneficial to know which sensing elements are receiving a beam spot and which are not, in order to dynamically update the group. However, this may pose some challenges. One challenge may be a lack of uniquely identifiable intensity readings from individual sensing elements during a beam mode operation. This is because, during beam mode, sensing elements may either be grouped together in a signal readout path, rendering their signals indistinguishable, or decoupled from the signal readout path entirely, potentially making them unreadable by the detector. Therefore, in a conventional sensing architecture, it may be difficult to determine which sensing elements should be added to, or removed from, a group.

In this disclosure, a detector with an improved architecture is provided for dynamically updating a group of sensing elements during use, such as in beam mode. The detector may comprise a plurality of sensing elements, with each sensing element having a threshold circuit configured to indicate whether a substantial portion of a beam spot is incident on the sensing element. When activated, the thresholding circuit may be configured to divert at least a portion of any signal (such as, e.g., a current) being generated at the sensing element and compare the signal to a predetermined threshold. The threshold may be a first high threshold (for adding a sensing element to a group) or a second low threshold (for removing a sensing element from the group). Depending on the comparison, a sensing element may be added to a group or removed from the group. A sensing element may be added to the group by closing a switching element in the switch matrix (thus forming a connection), or removed from the group by opening a switching element in the switch matrix (thus breaking a connection).

The thresholding circuit in a sensing element may be activated when the sensing element is determined to be a candidate for updating. A sensing element may be considered a candidate based on its proximity to a boundary of the sensing element group. For example, when a sensing element inside or outside the group is immediately adjacent to the grouping boundary, it may be a candidate. A controller may send a control signal to activate a thresholding operation by the threshold circuit. For example, the controller may be a local control circuit, such as a circuit within the detector. In some embodiments, the controller may be remote from the detector or remote from the substrate where sensing elements are located. The control signal may determine a threshold to be applied, as well as the switching element to be actuated if the threshold is met.

A process of identifying candidates and updating the sensing element groups may repeat continuously during a charged particle beam process. In this way, the sensing element groups may rapidly and accurately track any changes to a size, shape, location, or other property of a beam spot on the detector.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing detection systems and detection methods in systems utilizing electron beams (“e-beams”). However, the disclosure is not so limited. Other types of charged particle beams may be similarly applied. Furthermore, systems and methods for detection may be used in other imaging systems, such as optical imaging, photon detection, x-ray detection, ion detection, or the like.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Relative dimensions of components in drawings may be exaggerated for clarity. Within the following description of drawings, the same or like reference numbers refer to the same or like components or entities, and only the differences with respect to the individual embodiments are described.

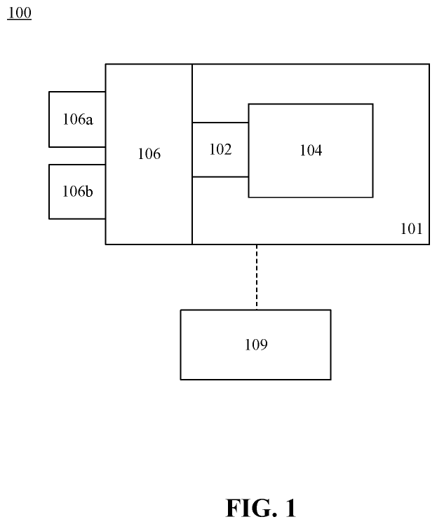

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

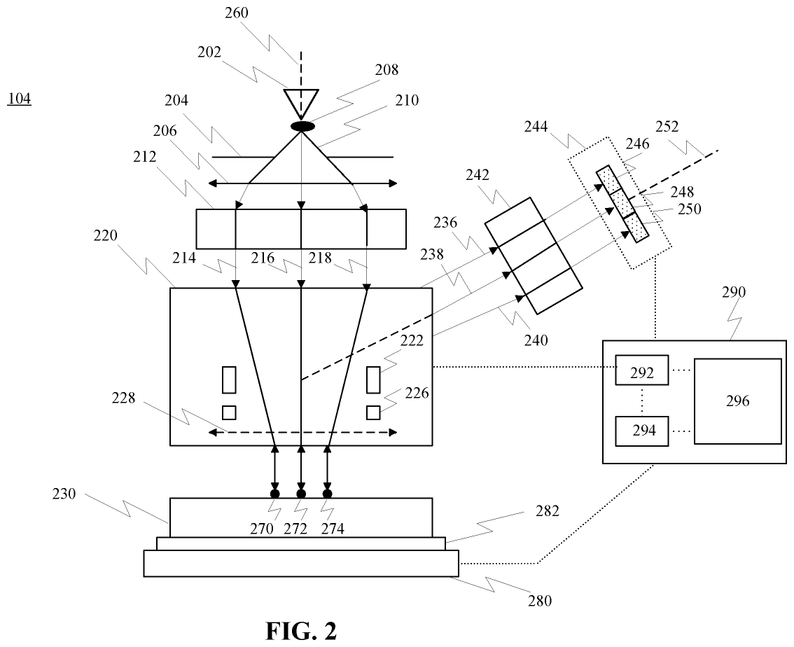

FIG. 2 illustrates a schematic diagram of an exemplary multi-beam beam tool 104 (also referred to herein as apparatus 104) and an image processing system 290 that may be configured for use in EBI system 100 (FIG. 1), consistent with embodiments of the present disclosure.

Beam tool 104 comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and charged-particle detection device 244 can be aligned with a secondary optical axis 252 of apparatus 104.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218. While three beamlets 214, 216, and 218 are shown in FIG. 2, embodiments of the present disclosure are not so limited. For example, in some embodiments, the apparatus 104 may be configured to generate a first number of beamlets. In some embodiments, the first number of beamlets may be in a range from 1 to 1000. In some embodiments, the first number of beamlets may be in a range from 200-500. In an exemplary embodiment, an apparatus 104 may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies ≤50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct an SCPM image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104 through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire SCPM images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and SEs depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 2). The quantity of BSEs and SEs may be more or fewer (or even the same) than the injected electrons of primary charged-particle beam 210.

The images generated by SEM may be used for defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, the SEM may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

For ease of explanation without causing ambiguity, electrons are used as examples in some of the descriptions herein. However, it should be noted that any charged particle may be used in any embodiment of this disclosure, not limited to electrons. For instance, a source in a charged-particle beam tool can emit one or more charged particles, such as electrons, protons, ions, muons, or any other particle carrying electric charges. Furthermore, some embodiments of the present disclosure may use photons instead of charged particles, such as light in the visible, UV, DUV, EUV, x-ray, or any other wavelength range. For example, in a photon embodiment, a secondary beam spot may refer to reflected, refracted, diffracted or scattered light from a sample upon which a primary light beam is incident. Therefore, while detectors in the present disclosure may be disclosed with respect to electron detection, some embodiments of the present disclosure may be directed to detecting other charged particles or photons.

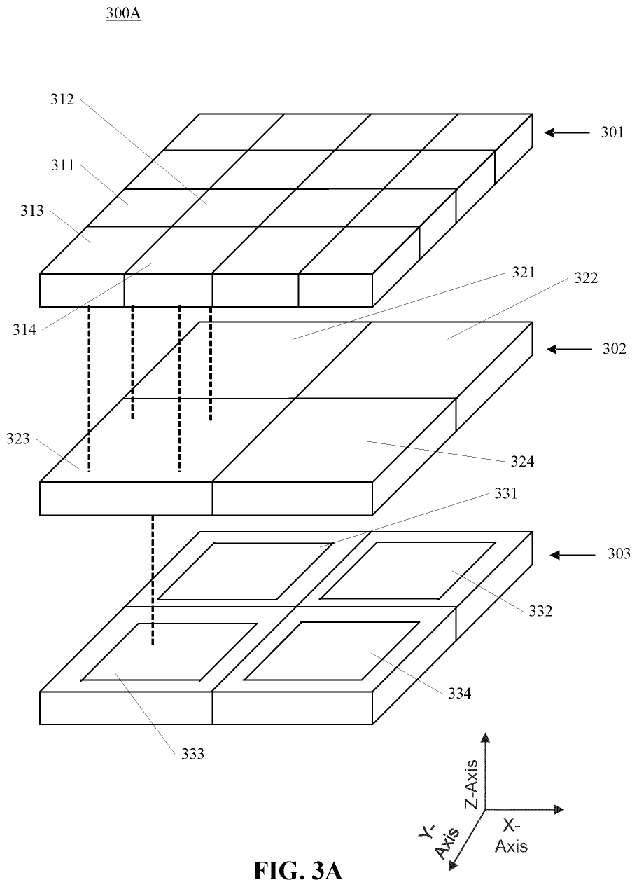

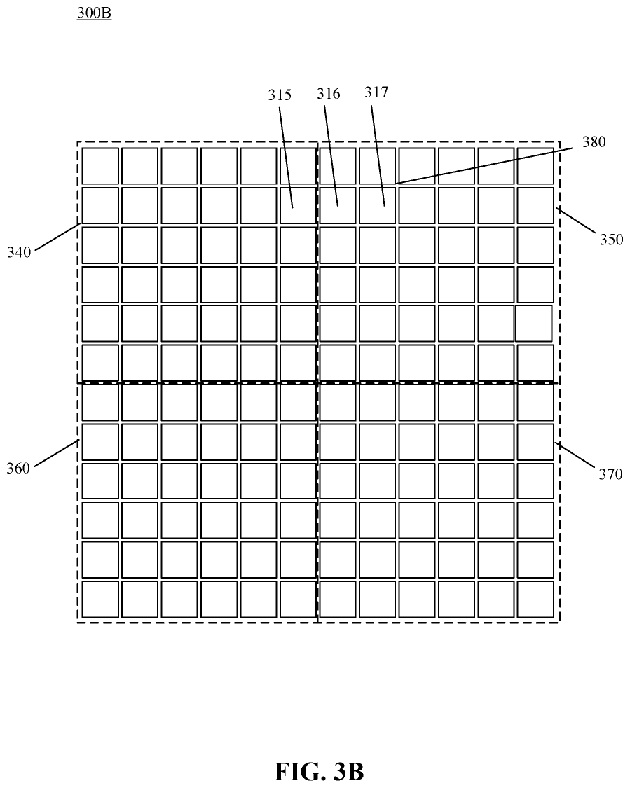

FIG. 3A illustrates a schematic representation of an exemplary structure of a detector 300A, consistent with embodiments of the present disclosure. Detector 300A may be provided as charged-particle detection device 244. In FIG. 3A, detector 300A includes a sensor layer 301, a section layer 302, and a readout layer 303. Sensor layer 301 may include a sensor die made up of multiple sensing elements, including sensing elements 311, 312, 313, and 314. In some embodiments, the multiple sensing elements may be provided in an array of sensing elements, each of which may have a uniform size, shape, and arrangement. Detector 300A may have an arrangement with respect to a coordinate axis reference frame. Sensor layer 301 may be arranged along an x-y plane. Sensing elements in sensor layer 301 may be arrayed in x-axis and y-axis directions. The x-axis direction may also herein be referred to as a “horizontal” direction. The y-axis direction may also herein be referred to as a “vertical” direction. Detector 300A may have a layer structure in which sensor layer 301, section layer 302, and section layer are stacked in a z-axis direction. The z-axis direction may also herein be referred to as a “thickness” direction. The z-axis direction may be aligned with a direction of incidence of charged particles that are directed toward detector 300A.

Section layer 302 may include multiple sections, including sections 321, 322, 323, and 324. The sections may include interconnections (e.g., wiring paths) configured to communicatively couple the multiple sensing elements. The sections may also include switching elements that may control the communicative couplings between the sensing elements. The sections may further include connection mechanisms (e.g., wiring paths and switching elements) between the sensing elements and on or more common nodes in the section layer. For example, as shown in FIG. 3A, section 323 may be configured to communicatively couple to outputs of sensing elements 311, 312, 313, and 314, as shown by the four dashed lines between sensor layer 301 and section layer 302. In some embodiments, section 323 may be configured to output combined signals gathered from sensing elements 311, 312, 313, and 314 as a common output. In some embodiments, a section (e.g., section 323) may be communicatively coupled to sensing elements (e.g., sensing elements 311, 312, 313, and 314) placed directly above the section. For example, section 323 may have a grid of terminals configured to connect with the outputs of sensing elements 311, 312, 313, and 314. In some embodiments, sections 321, 322, 323, and 324 may be provided in an array structure such that they have a uniform size and shape, and a uniform arrangement. Sections 321, 322, 323, and 324 may be square shaped, for instance. In some embodiments, an isolation area may be provided between adjacent sections to electrically insulate them from one another. In some embodiments, sections may be arranged in an offset pattern, such as a tile layout.

Readout layer 303 may include signal processing circuits for processing outputs of the sensing elements. In some embodiments, signal processing circuits may be provided, which may correspond with each of the sections of section layer 302. In some embodiments, multiple separate signal processing circuitry sections may be provided, including signal processing circuitry sections 331, 332, 333, and 334. In some embodiments, the signal processing circuitry sections may be provided in an array of sections having a uniform size and shape, and a uniform arrangement. In some embodiments, the signal processing circuitry sections may be configured to connect with an output from corresponding sections of section layer 302. For example, as shown in FIG. 3A, signal processing circuitry section 333 may be configured to communicatively couple to an output of section 323, as shown by the dashed line between section layer 302 and readout layer 303.

In some embodiments, readout layer 303 may include input and output terminals. Output(s) of readout layer 303 may be connected to a component for reading and interpreting the output of detector 300A. For example, readout layer 303 may be directly connected to a digital multiplexer, digital logic block, controller, computer, or the like.

The sizes of sections and the number of sensing elements associated with a section may be varied. For example, while FIG. 3A illustrates a 2×2 array of four sensing elements in one section, embodiments of the disclosure are not so limited. In some embodiments of the present disclosure, a section may include a 3×3, 4×4, 5×5, 6×6, 2×4 or 1×6 array or any other suitable arrangement of sensing elements.

While FIG. 3A illustrates sensor layer 301, section layer 302, and readout layer 303 as multiple discrete layers, it is noted that sensor layer 301, section layer 302, and readout layer 303 need not be provided as separate substrates. For example, a wiring path of section layer 302 may be provided in a sensor die including the multiple sensing elements, or may be provided outside of the sensor die. Wiring paths may be patterned on sensor layer 301. Additionally, section layer 302 may be combined with readout layer 303. For example, a semiconductor die may be provided that includes wiring paths of section layer 302 and signal processing circuits of readout layer 303. Thus, structures and functionalities of the various layers may be combined or divided.

In some embodiments, a detector may be provided in a two-die configuration. However, embodiments of the present disclosure are not so limited. For example, functions of a sensor layer, section layer, and readout layer may be implemented in one die or in a package that may contain one or more dies.

In some embodiments, arrangements of sensor layer 301, section layer 302, and readout layer 303 may correspond with one another in a stacked relationship. For example, section layer 302 may be mounted directly on top of readout layer 303, and sensor layer 301 may be mounted directly on top of section layer 302. The layers may be stacked such that sections within section layer 302 are aligned with signal processing circuitry sections (e.g., sections 331, 332, 333, and 334) of readout layer 303. Furthermore, the layers may be stacked such that one or more sensing elements within sensor layer 301 are aligned with a section in section layer 302. In some embodiments, sensing elements to be associated with a section may be contained within the section. For example, in a plan view of detector 300A, sensing elements (e.g., sensing elements 311, 312, 313, and 314) of a section (e.g., section 323) may fit within the boundaries of the section. Furthermore, individual sections of section layer 302 may overlap with signal processing circuitry sections of readout layer 303. In this manner, predefined areas may be established for associating sensing elements with sections and signal processing circuitry.

FIG. 3B illustrates an exemplary structure of a sensor surface 300B that may form a surface of charged-particle detection device 244, consistent with embodiments of the present disclosure. Sensor surface 300B may be provided with multiple sections of sensing elements, including sections 340, 350, 360, and 370, which are represented by the dashed lines. For example, sensor surface 300B may be the surface of sensor layer 301 in FIG. 3A. Each section may be capable of receiving at least a part of a beam spot emitted from a particular location from wafer 230, such as one of secondary charged-particle beams 236, 238, and 240 as shown in FIG. 2.

Sensor surface 300B may include an array of sensing elements, including sensing elements 315, 316, and 317. In some embodiments, each of sections 340, 350, 360, and 370 may contain one or more sensing elements. For example, section 340 may contain a first plurality of sensing elements, and section 350 may contain a second plurality of sensing elements, and so on. The first plurality of sensing elements and the second plurality of sensing elements may be mutually exclusive. In the example embodiment of FIG. 3B, each of sections 340, 350, 360, and 370 comprises a 6×6 array of sensing elements. In some embodiments, a sensing element may be a diode or any element similar to a diode that can convert incident energy into a measurable signal. For example, the sensing elements may include a PIN diode, an avalanche diode, an electron multiplier tube (EMT), or other components.

In FIG. 3B, an area 380 may be provided between adjacent sensing elements. Area 380 may be an isolation area to isolate the sides or corners of neighboring sensing elements from one another. In some embodiments, area 380 may include an insulating material that is different from that of the sensing elements of sensor surface 300B. In some embodiments, area 380 may be provided as a square. In some embodiments, area 380 may not be provided between adjacent sides of sensing elements.

In some embodiments, a field programmable detector array may be provided with sensing elements having switching regions integrated between the sensing elements. For example, detectors may be provided such as some of those examples discussed in PCT Application No. PCT/EP2018/074833, filed on Sep. 14, 2018, the content of which is herein incorporated by reference in its entirety. In some embodiments, a switching region may be provided between sensing elements so that some or more of the sensing elements may be grouped when covered by the same charged-particle beam spot. Circuits for controlling the switching regions may be included in the signal processing circuits of the readout layer (e.g., readout layer 303 in FIG. 3A). As used throughout the present disclosure, the expression “group” of sensing elements may refer to sensing elements that are associated with one beam spot projected on a detector surface (e.g., within the boundary of the beam spot). A “switch matrix” may refer to all or part of a network of switching elements within a detector architecture configured to selectively connect the various elements and wiring paths in a detector and related control circuitry.

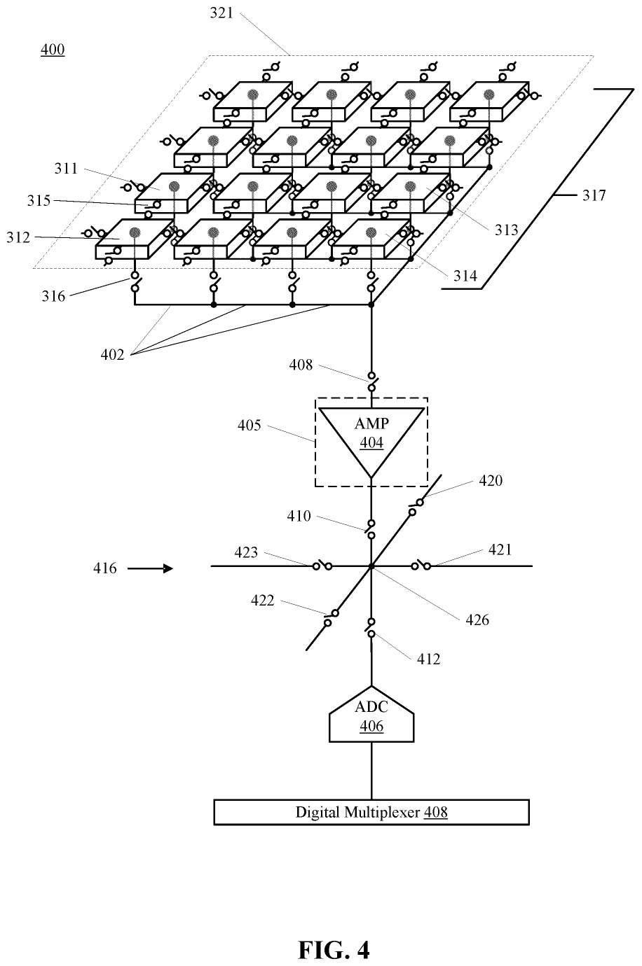

FIG. 4 is a diagram illustrating an exemplary detector array 400 with switching elements, consistent with embodiments of the present disclosure. The architecture of FIG. 4 may be used in either a single-beam inspection tool or a multibeam inspection tool (e.g., beam tool 104 in FIG. 2). Detector array 400 may be an example embodiment of detector 300A in FIG. 3A. For example, detector array 400 may include a sensor layer (e.g., similar to sensor layer 301 in FIG. 3A), a section layer (e.g., similar to section layer 302 in FIG. 3A), and a readout layer (e.g., similar to readout layer 303 in FIG. 3A). The sensor layer of detector array 400 may include multiple sensing elements, including sensing elements 311, 312, 313, and 314. In some embodiments, each of the sensing elements of detector array 400 may have a uniform size, shape, and arrangement. The sensing elements of detector array 400 may generate an electric current signal commensurate with the charged particles (e.g., exiting electrons) received in the active areas of the sensing elements. The “active areas” herein may refer to areas of the sensing elements having radiation sensitivity above a predetermined threshold value.

The section layer of detector array 400 may include a base substrate (e.g., a semiconductor substrate, not shown in FIG. 4) including one or more wiring paths 402. Wiring paths 402 may be configured to communicatively couple the sensing elements of detector array 400. As shown in FIG. 4, detector array 400 includes a section 321 having 4×4 sensing elements, including sensing elements 311, 312, 313, and 314. In FIG. 4, the section layer of detector array 400 may include inter-element switching elements 315 between any two adjacent sensing elements. The section layer of detector array 400 may also include inter-element switching elements 315 communicatively coupled to edges of neighboring sensing elements. Wiring paths 402 may be configured to communicatively couple to outputs of sensing elements (e.g., sensing elements 311, 312, 313, and 314) in section 321. For example, wiring paths 402 may have a grid of terminals (shown as round black dots at the centers of the sensing elements) configured to connect with the outputs of sensing elements 311, 312, 313, and 314. In some embodiments, wiring paths 402 may be provided in the section layer of detector array 400. In FIG. 4, wiring paths 402 are communicatively coupled to the above sensing elements (e.g., sensing elements 311, 312, 313, and 314). In FIG. 4, element-bus switching elements 316 may be provided between the outputs of the sensing elements and wiring paths 402. In some embodiments, the element-bus switching elements 316 may be provided in the section layer of detector array 400.

In some embodiments, wiring paths 402 may include lines of conductive material printed on the base substrate, flexible wires, bonding wires, or the like. In some embodiments, switching elements may be provided so that outputs of individual sensing elements can be connected or disconnected with the common output of section 321. In some embodiments, the section layer of detector array 400 may further include corresponding circuits for controlling the switching elements. In some embodiments, switching elements may be provided in a separate switch-element matrix that may itself contain circuits for controlling the switching elements.

The readout layer of detector array 400 may include signal conditioning circuits for processing outputs of the sensing elements. In some embodiments, the signal conditioning circuits may convert the generated current signal into a voltage that may represent the intensity of a received beam spot or may amplify the generated current signal into an amplified current signal. The signal conditioning circuit may include, for example, an amplifier 404 and one or more analog switching elements. The amplifier 404 may be a high speed transimpedance amplifier, a current amplifier, or the like. In FIG. 4, amplifier 404 may be communicatively coupled to the common output of section 321 for amplifying the output signals of the sensing elements of section 321. In some embodiments, amplifier 404 may be a single-stage or a multi-stage amplifier. For example, if amplifier 404 is a multi-stage amplifier, it may include a pre-amplifier and a post-amplifier, or include a front-end stage and a post stage, or the like. In some embodiments, amplifier 404 may be a variable gain amplifier, such as a variable gain transimpedance amplifier (VGTIA), a variable gain charge transfer amplifier (VGCTA), or the like. The conditioning circuit may be coupled to a signal path that may include, for example, an analog-to-digital converter (ADC) 406. In FIG. 4, ADC 406 may be communicatively coupled to the output of the conditioning circuit (e.g., including amplifier 404) to convert the analog output signals of the sensing elements of section 321 to digital signals. The readout layer of detector array 400 may also include other circuits for other functions. For example, the readout layer of detector array 400 may include switch-element actuating circuits that may control the switching elements between the sensing elements. For ease of explanation without causing ambiguity, the signal path between the sensing elements and ADC 406 may be referred to as an “analog signal path.” For example, the analog signal path in FIG. 4 includes the above-described signal conditioning circuit (e.g., including amplifier 404). The input of the analog signal path is communicatively coupled to the sensing elements, and the output of the analog signal path is communicatively coupled to ADC 406. The signal path between the sensing elements and a readout layer may be referred to as a “signal readout path,” and may be the same as, or different from, the analog signal path. For example, the signal readout path may include the analog signal path, or multiple analog signal paths, and may extend further into a readout layer of the detector 400, such as to digital multiplexer 408.

In some embodiments, ADC 406 may include output terminals communicatively coupled to a component (e.g., a component inside or outside the readout layer of detector array 400) for reading and interpreting the digital signal converted by ADC 406. In FIG. 4, ADC 406 is communicatively coupled to a digital multiplexer 408. In some embodiments, digital multiplexer 408 may be arranged in the readout layer of detector array 400. Digital multiplexer 408 may receive multiple input signals and convert them as an output signal. The output signal of digital multiplexer 408 may be converted back to the multiple input signals. The output signal of digital multiplexer 408 may be further transmitted to a data processing stage (e.g., image processing system 290 in FIG. 2).

In some embodiments of the present disclosure, detector 400 may include a further layer of switching elements, such as interconnection layer 416 that communicatively couples outputs of signal processing circuitry to each other. The signal processing circuitry may include analog signal paths. As shown in FIG. 4, interconnection layer 416 includes interconnection switching elements communicatively coupled to outputs of analog signal paths of detector array 400. For example, interconnection switching elements 420-423 may communicatively couple the outputs of adjacent analog signal paths. Detector array 400 includes an analog signal path 405 associated with section 321, which starts from the output of section 321 and ends at the input of an interconnection layer 416.

In FIG. 4, a switching element 408 may communicatively couple an output of section 321 to an input of analog signal path 405, and switching element 410 may communicatively couple an output of analog signal path 405 to an input (e.g., input/output point 426 or “I/O point” 426) of interconnection layer 416. Switching elements 408 and 410 may be configured to be communicatively disconnected if analog signal path 405 is not selected for use. For example, a charged-particle beam may impinge on some or all of the sensing elements of section 321, but the detection signals of section 321 may be redirected to another analog signal path corresponding to another section of detector array 400, as further discussed below. In such a case, analog signal path 405 may be disconnected as a result of not being selected. In some embodiments, if no sensing element of section 321 is impinged by any charged-particle and analog signal path 405 is not selected for use (e.g., to process signal from other sections), besides communicatively disconnecting switching elements 408 and 410, amplifier 404 may also be disabled to reduce power consumption. When switching elements 408 and 410 are communicatively disconnected, analog signal path 405 (including amplifier 404) may be effectively deactivated from detector array 400.

The switch matrix comprising, e.g., inter-element switching elements 315, element-bus switching elements 316, and interconnection switching elements 420-423 may be configured to route signals from sensing elements to the readout layer of detector array 400 by a variety of signal readout paths. For example, when only one beam spot is incident on section 321, sensing elements may be coupled to the readout layer via element bus switching elements 316 and switching elements 408-410. For instance, if a beam spot has been determined previously (such as during as picture mode) to be incident on all sensing elements in section 321, then the entire section may be coupled to the signal readout path via element-bus switching elements at each sensing element in section 321. Inter-element switching elements 315 between the sensing elements in section 321 may be left open to reduce parasitic parameters such as series resistance and parasitic capacitance. If, for example, sensing elements 311 and 312 are determined to be receiving a portion of a beam spot and the remaining sensing elements of section 321 are not, then only sensing elements 311-312 may be connected by closing their element-bus switching elements 316, while the remaining sensing elements are disconnected by leaving their own element-bus switching elements 316 open.

At the same time, sensing elements from neighboring sections may be coupled to a common signal readout path at interconnection layer 416 via interconnect switches 420-423. Alternatively, sensing elements from a neighboring section may be coupled to sensing elements within section 321 by closing the inter-element switching elements 315 between them.

If it is determined that two different beam spots are incident on two different portions of section 321, then signals from the two beam spots must be routed along different signal readout paths in order to differentiate them. In this case it is not possible for both portions to be coupled to analog signal path 405. For example, a first beam spot may be incident on sensing elements 311-312, as well as the neighboring section to the left of section 321 in FIG. 4 (not shown). A second beam spot may be incident on the entire row 317 containing sensing elements 313 and 314, as well as the neighboring section to the right of section 321 in FIG. 4 (not shown). If both sets of sensing elements are routed through analog signal path 405, their signals would not be differentiable. Therefore at least one of the portions may be connected to the adjacent section that shares a common beam spot.

For instance, sensing elements 311 and 312 may be connected to the neighboring section on the left side of section 321 by the inter-element switching elements on their left sides in FIG. 4. The neighboring section to the left may then be routed along an analog signal path other than analog signal path 405. Furthermore, interconnection switching element 423 may be open to disconnect the neighboring section from a signal readout path comprising analog signal path 405. At the same time, row 317 may be coupled to analog signal path 405 via their element-bus switching elements 316. Analog signal path 405 may be connected to an analog signal path of the neighboring section to the right by, e.g., closing interconnection switching element 421. Thus row 317 may be coupled to its adjacent section without closing the inter-element switching elements 315 between them.

The decision to route the two portions in the example way discussed above may be determined based on, e.g., a desire to minimize the parasitic parameters in the system. For example, if parallel paths along element-bus switching elements 316 are preferred over series paths along inter-element switching elements 315, the routing may be determined such that fewer inter-element switching elements 315 are connected to the system. A total measure of parasitic parameters may be considered when determining optimal signal readout paths.

Further details of detector array 400 may be found in U.S. Provisional Patent Application No. 63/019,179, which is incorporated herein by reference in its entirety.

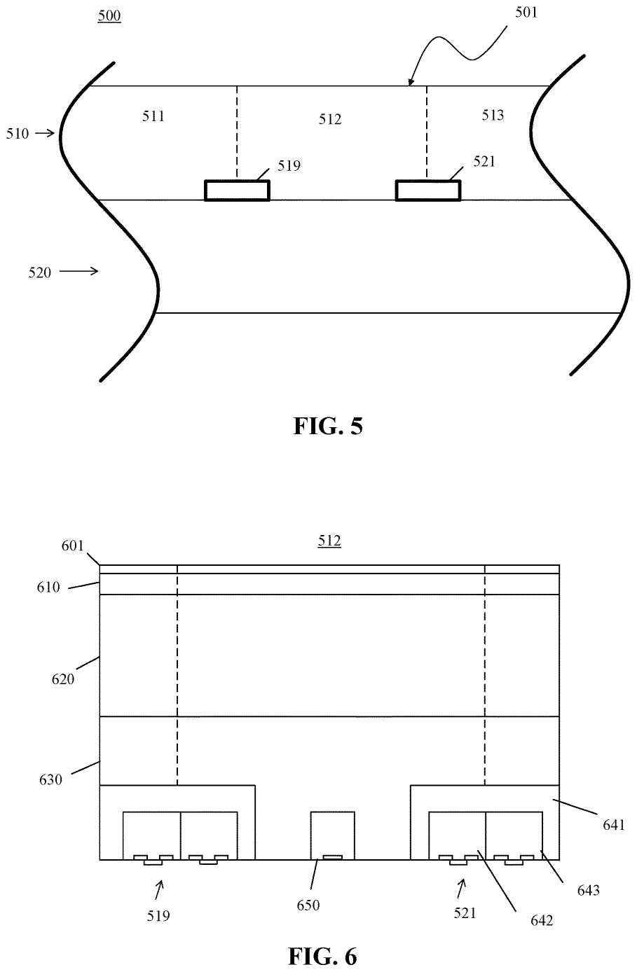

FIG. 5 is a diagram illustrating a cross-sectional view of a layer structure of a detector 500, consistent with embodiments of the present disclosure. Detector 500 may be provided as charged-particle detection device 244 in a charged-particle beam tool 104 as shown in FIG. 2. Detector 500 may be configured to have multiple layers stacked in a thickness direction, the thickness direction being substantially parallel to an incidence direction of a charged-particle beam. In some embodiments, detector 500 may be provided such as some of those examples discussed in PCT Application No. PCT/EP2018/074834, filed on Sep. 14, 2018, the content of which is herein incorporated by reference in its entirety.

In FIG. 5, detector 500 may include a sensor layer 510 and a circuit layer 520. In some embodiments, sensor layer 510 may represent sensor layer 301 in FIG. 3A, and circuit layer 520 may represent section layer 302 and readout layer 303 in FIG. 3A. For example, circuit layer 520 may include interconnects (e.g., metal lines), and various electronic circuit components. As another example, circuit layer 520 may include a processing system. Circuit layer 520 may also be configured to receive the output current detected in sensor layer 510. In some embodiments, sensor layer 510 may represent sensor layer 301 and section layer 302 in FIG. 3A, and circuit layer 520 may represent readout layer 303 in FIG. 3A. In some embodiments, detector 500 may include layers in addition to sensor layer 301, section layer 302, and readout layer 303.

In some embodiments, sensor layer 510 may be provided with a sensor surface 501 for receiving incident charged particles. Sensing elements, including sensing elements 511, 512, and 513 (differentiated by dashed lines), may be provided in sensor layer 510. For example, sensor surface 501 may be similar to sensor surface 300B in FIG. 3B. In FIG. 5, switching elements, including switching elements 519 and 521, may be provided between adjacent sensing elements in a horizontal direction in the cross-sectional view. Switching elements 519 and 521 may be embedded in sensor layer 510. In some embodiments, sensing elements 511, 512, and 513 may be among the sensing elements (e.g., sensing elements 311, 312, 313, and 314) of detector array 400 in FIG. 4, and switching elements 519 and 521 may be among the switching elements between the sensing elements of detector array 400 in FIG. 4.

In some embodiments, sensing elements 511, 512, and 513 may be separated by an isolation area (indicated by the dashed lines) extending in the thickness direction. For example, sides of sensing elements 511, 512, and 513 that are parallel to the thickness direction may be isolated from each other by the isolation areas (e.g., area 380 in FIG. 3B).

In some embodiments, sensor layer 510 may be configured as one or more diodes where sensing elements 511, 512, and 513 are similar to sensing elements 315, 316, and 317 of FIG. 3B. Switching elements 519 and 521 may be configured as transistors (e.g., MOSFETs). Each of sensing elements 511, 512, 513 may include outputs for making electrical connections to circuit layer 520. For example, the outputs may be integrated with switching elements 519 and 521, or they may be provided separately. In some embodiments, the outputs may be integrated in a bottom layer of sensor layer 510 (e.g., a metal layer).

Although FIG. 5 depicts sensing elements 511, 512, and 513 as discrete units when viewed in cross-section, such divisions may not actually be physical. For example, the sensing elements of detector 500 may be formed by a semiconductor device constituting a PIN diode device that can be manufactured as a substrate with multiple layers including a P-type region, an intrinsic region, and an N-type region. In such an example, sensing elements 511, 512, 513 may be contiguous in cross-sectional view. In some embodiments, the switching elements (e.g., switching elements 519 and 521) may be integrated with the sensing elements.

In some embodiments, switching elements may be integrated within the sensor layer, integrated within other layers, or may be provided partially or fully in existing layers. In some embodiments, for example, the sensor layer may contain wells, trenches, or other structures, wherein the switching elements are formed in those structures.

In some embodiments, the switching elements (e.g., switching elements 519 and 521) of detector 500 may be provided outside of sensor layer 510. For example, the switching elements may be embedded in circuit layer 520 (not shown in FIG. 5). In some embodiments, the switching elements (e.g., switching elements 519 and 521) of detector 500 may be formed in a separate die (e.g., a switch die). For example, the switch die (not shown in FIG. 5) may be sandwiched between and be communicatively connected to sensor layer 510 and circuit layer 520.

FIG. 6 is a diagram illustrating a cross-sectional view of sensing element 512 of detector 500, consistent with embodiments of the present disclosure. In FIG. 6, sensing element 512 may include a P-well and an N-well for forming switching elements and other active or passive elements that may be communicatively coupled to other components of sensor layer 510 or circuit layer 520. Although FIG. 6 only shows one full sensing element 512, it is understood that sensor layer 510 may be made up of multiple sensing elements similar to sensing element 512 (e.g., sensing elements 511 and 513), which may be contiguous in cross-sectional view.

In some embodiments, sensing element 512 may include a diode device having a surface layer 601, a P-type region 610, a P-epitaxial region 620, an N-type region 630, and other components. Surface layer 601 may form a detection surface (e.g., an active area) of a detector that receives incident charged particles. For example, surface layer 601 may be a metal layer (e.g., formed by aluminum or other conductive materials). On an opposite side from surface layer 601, there may be provided an electrode 650 as a charge collector. Electrode 650 may be configured to output a current signal representing the number of charged particles received in the active area of sensing element 512.

In some embodiments, as shown in FIG. 6, switching elements 519 and 521 may be formed by metal oxide semiconductor (MOS) devices. For example, multiple MOS devices may be formed in a back side of N-type region 630 in FIG. 6, and the back side of N-type region 630 may be in contact with sensor layer 510 in FIG. 5. As an example of a MOS device, there may be provided a deep P-well 641, an N-well 642, and a P-well 643. In some embodiments, the MOS devices may be fabricated by etching, patterning, and other processes and techniques. It will be understood that various other devices may be used, such as bipolar semiconductor devices, etc., and devices may be fabricated by various processes.

In operation of sensing element 512, when charged particles (e.g., secondary charged-particle beams 236, 238, and 240 in FIG. 2) impinge on surface layer 601, the body of sensing element 512, including, e.g., a depletion region, may be flooded with charge carriers generated from the impinged charged particles. Such a depletion region may extend through at least a portion of the volume of the sensing element. For example, the charged particles may be electrons, and the impinged electrons may create and energize electron-hole pairs in a depletion region of the sensing element. The energized electrons among the electron-hole pairs may have further energy such that they may also generate new electron-hole pairs. Electrons generated from the impinged charged particles may contribute to signal generated in each sensing element.

With reference to FIG. 6, a depletion region in sensing element 512 may include an electric field between P-type region 610 and N-type region 630, and the electrons and the holes may be attracted by P-type region 610 and N-type region 630, respectively. When the electrons reach P-type region 610 or when the holes reach N-type region 630, a detection signal may be generated. Thus, sensing element 512 may generate an output signal, such as current, when a charged particle beam is incident on sensing element 512. Multiple sensing elements may be connected, and a group of sensing elements may be used to detect intensity of a charged particle beam spot. When a charged particle beam spot covers multiple adjacent sensing elements (e.g., sensing elements 511, 512, and 513), the sensing elements may be grouped together (“merged”) for collecting current. For example, the sensing elements may be merged by turning on switching elements (e.g., switching elements 519 and 521) between them. Signals from sensing elements in a group may be collected and sent to a signal conditioning circuit connected to the group. The number of sensing elements in a group may be an arbitrary number related to the size and shape of the beam spot. The number may be 1 or greater than 1.

In some embodiments, a detector may be configured so that individual sensing elements may communicate with external components via, for example, signal or data lines and address signals. A detector may be configured to actuate switching elements so that two or more sensing elements may be merged, and their output current or voltage may be combined. As can be seen in FIGS. 5-6, with the switch-element design between the sensing elements, the sensing elements may be provided without physical isolation areas (e.g., area 380 in FIG. 3B). Thus, when sensing element 512 is activated, all of the area under surface layer 601 may become active. When no physical isolation area is provided between adjacent sensing elements, dead area between them may be minimized or eliminated.

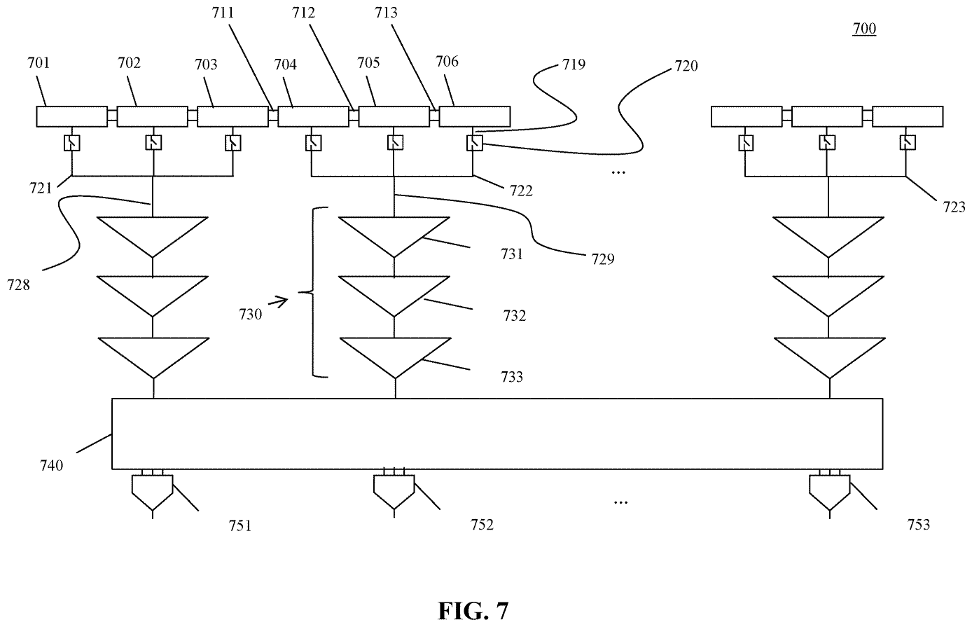

FIG. 7 is a diagram representing an exemplary section arrangement of a detector 700, consistent with embodiments of the present disclosure. For example, detector 700 may be an embodiment of detector 300A in FIG. 3A, detector array 400 in FIG. 4, or detector 500 in FIG. 5. As shown in FIG. 7, detector 700 may include multiple sensing elements, including sensing elements 701, 702, 703, 704, 705, and 706. In some embodiments, the multiple sensing elements may be part of a sensor layer that may form a detection surface (e.g., sensor surface 300B in FIG. 3B) of charged-particle detection device 244 in FIG. 2. The sensor layer may include switching elements between adjacent sensing elements (e.g., similar to switching elements 519 and 521 in FIG. 6), including inter-element switching elements 711, 712, and 713. In some embodiments, when being turned on, the switching elements may be configured to group two or more adjacent sensing elements together.

In FIG. 7, detector 700 may include multiple sections (e.g., similar to sections 321, 322, 323, and 324 in FIG. 3A). Each of the sections may include one or more sensing elements, and wiring paths (e.g., similar to wiring paths 402 in FIG. 4) between the sensing elements, and a common output. In some embodiments, the wiring paths may include a common wire or a shared signal path. For example, as shown in FIG. 7, wiring paths 721 may be communicatively connected to sensing elements 701, 702, and 703, and to a common output 728. Wiring paths 721, sensing elements 701-703, and common output 728 may belong to a first section. Wiring paths 722 may be communicatively connected to sensing elements 704, 705, and 706, and to a common output 729. Wiring paths 722, sensing elements 704-706, and common output 729 may belong to a second section. An output (e.g., output 719) of a sensing element (e.g., sensing element 706) may be communicatively coupled to corresponding wiring paths (e.g., wiring paths 722) via an element-bus switching element (e.g., element-bus switching element 720). In some embodiments, element-bus switching element 720 may be implemented using techniques similar to switching elements 519 and 521 as described in FIG. 6. In some embodiments, when sensing element 706 is inactive, element-bus switching element 720 may be disconnected to reduce noise, parasitic capacitance, or other technical effects from sensing element 706.

In FIG. 7, the sections (e.g., the first section including sensing elements 701-703 or the second section including sensing elements 704-706) may be configured to output electrical signals to signal processing circuits and further circuit elements. For example, wiring paths 722 may output electrical signals to signal processing circuitry 730 via common output 729.

Signal processing circuitry 730 may include one or more signal processing circuits for processing electrical signals output by wiring paths 722. For example, signal processing circuitry 730 may include a pre-amplifier 731, a post-amplifier 732, and a data converter 733. For example, pre-amplifier 731 may be a transimpedance amplifier (TIA), a charge transfer amplifier (CTA), a current amplifier, or the like. Post-amplifier 732 may be a variable gain amplifier (VGA) or the like. Data converter 733 may be an analog-to-digital converter (ADC), which may convert an analog voltage or an analog current to a digital value. In some embodiments, pre-amplifier 731 and post-amplifier 732 may be combined as a single amplifier (e.g., amplifier 404 in FIG. 4), and data converter 733 may include ADC 406 in FIG. 4.

Detector 700 may include a digital switch 740. In some embodiments, digital switch 740 may include a switch-element matrix. In some embodiments, digital switch 740 may include a multiplexer (e.g., digital multiplexer 408 in FIG. 4). For example, the multiplexer may be configured to receive a first number of inputs and generate a second number of outputs, in which the first number and the second number may be the same or different. The first number may correspond to parameters (e.g., a total number of sections) of detector 700, and the second number may correspond to parameters (e.g., number of beamlets generated from charged-particle source 202 in FIG. 2) of beam tool 104 of FIGS. 1-2. Digital switch 740 may communicate with external components via data line(s) and address signal(s). In some embodiments, digital switch 740 may control data read/write. Digital switch 740 may also include circuitry for controlling the inter-element switching elements (e.g., inter-element switching elements 711, 712, and 713). In FIG. 7, digital switch 740 may generate output signals via multiple data channels, including data channels 751, 752, and 753. In some embodiments, the data channels of digital switch 740 may be further connected to other components (e.g., relays or the like). Thus, multiple sections of detector 700 may act as independent data channels for detector signals.

It is noted that various components may be inserted at various stages in the representation of FIG. 7. In some embodiments, one or more of the above components of detector 700 may be omitted. In some embodiments, other circuits may be provided for other functions. For example, switch-element actuating circuits (not shown in FIG. 7) may be provided to control inter-element switching elements (e.g., inter-element switching elements 711, 712, and 713) for connecting the sensing elements. In some embodiments, an analog output line (not shown in FIG. 7) may be provided, which can be read by an analog path. For example, the analog output line may be parallel to data converter 733 for receiving output of post-amplifier 732. For another example, the analog output line may replace data converter 733.

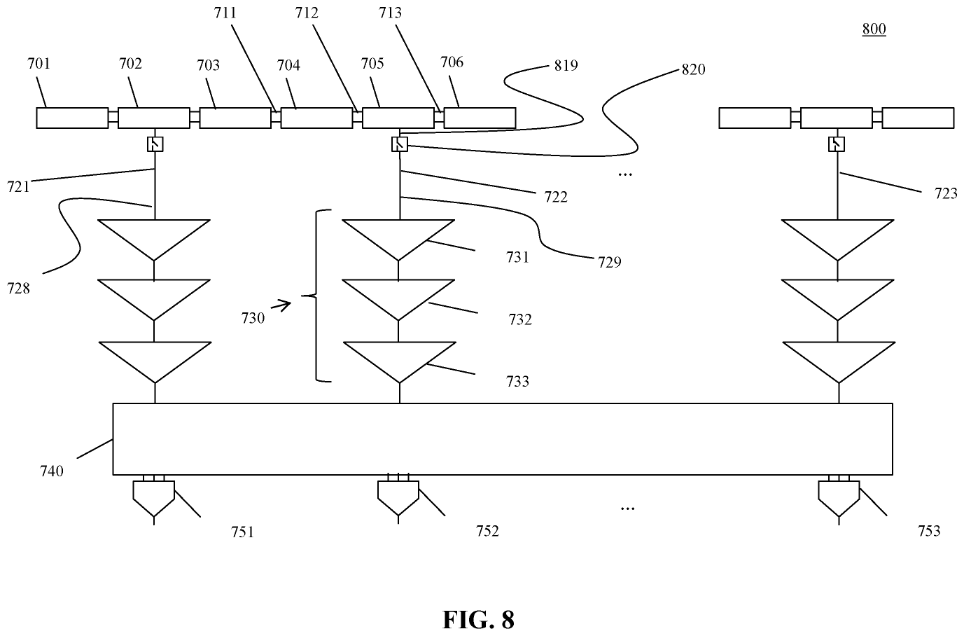

FIG. 8 is a diagram representing another exemplary section arrangement of detector 800, consistent with embodiments of the present disclosure. Detector 800 may be similar to detector 700 except that sensing elements (e.g., sensing elements 704, 705, and 706) associated with a section may be communicatively coupled to associated wiring paths (e.g., wiring paths 722) via a common wiring path (e.g., common wiring path 819) and a common switching element (e.g., common switching element 820). In some embodiments, common switching element 820 may be implemented using techniques similar to switching elements 519 and 521 as described in FIG. 6. For example, as shown in FIG. 8, if a charged-particle beam is incident on sensing elements 704, 705, and 706, sensing elements 704, 705, and 706 may generate detection signals. Sensing element 705 may directly output its detection signal to common wiring path 819. Sensing elements 704 and 706 may route their detection signals to sensing element 705 through inter-element switching elements 712 and 713, respectively, which may be further routed to common wiring path 819 via sensing element 705. Such a design may simplify manufacturing of a detector. As a comparison, a design that uses multiple wiring paths and switching elements between the sensing elements and sections (e.g., the design of detector 700 in FIG. 7) may provide configuration flexibility to group sensing elements because an output of a section is not fixed at any specific sensing element (e.g., sensing element 705 in FIG. 8) of that section. In addition, designs such as that of detector 700 in FIG. 7 may enhance simplicity in reading the output of individual sensing elements. To acquire the beam projection of secondary electron beams, it may be advantageous to read out the output of each sensing element so that the image of the projection pattern may be acquired.

In some embodiments of the present disclosure, the configurations of FIGS. 7 and 8 may comprise interconnection layers, such as 416 in FIG. 4. Such configurations can be found in the above-incorporated U.S. Provisional Patent Application No. 63/019,179.

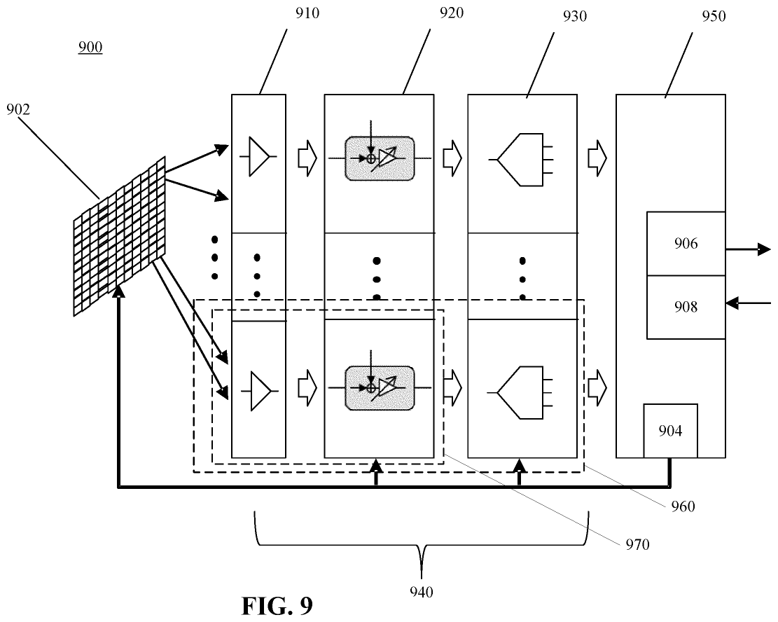

FIG. 9 is a diagram representing a detection system 900, consistent with embodiments of the present disclosure. In some embodiments, detection system 900 may be an embodiment of detection device 244 in FIG. 2. Detection system 900 may include sensing elements 902 (e.g., similar to the sensing elements as described in FIGS. 3A-8) and processing circuits 940 (e.g., similar to signal processing circuitry 730 in FIGS. 7-8). Processing circuits 940 may be communicatively coupled to a digital interface 950 (e.g., similar to digital switch 740 in FIGS. 7-8). Sensing elements 902 may form a sensor surface (e.g., sensor surface 300B of FIG. 3B), and may be segmented into sections (e.g., similar to the sections as described in FIGS. 3A-3B or FIGS. 7-8). Processing circuits 940 may include a first processing circuit array 910 (e.g., including pre-amplifier 731 in FIGS. 7-8) for processing outputs of sensing elements 902, a second processing circuit array 920 (e.g., including post-amplifier 732 in FIGS. 7-8) for providing gains and offset controls, and an ADC array 930 (e.g., including data converter 733 in FIGS. 7-8) for converting analog signals to digital signals. The first processing circuit array 910 and the second processing circuit array 920 may form signal conditioning circuits in processing circuits 940. Each section of processing circuits 940 may be communicatively coupled to a section of sensing elements 902, which may be orderly, communicatively coupled to a unit of first processing circuit array 910, a unit of second processing circuit array 920, and a unit of ADC array 930, forming a signal path (e.g., signal path 960). Such a signal path may receive output signals from the section of sensing elements 902 and generate a charged-particle detection current representing the intensity of at least a portion of a charged-particle beam spot formed on the section of sensing elements 902. The charged-particle detection data may be output to digital interface 950. In FIG. 9, signal path 960 includes an analog signal path 970, which includes the unit of first processing circuit array 910 and the unit of second processing circuit array 920.

Digital interface 950 may include a controller 904. Controller 904 may communicate with ADC array 930, second processing circuit array 920, and sensing elements 902. Digital interface 950 can also send and receive communications from a deflection and image control unit (not shown in FIG. 9) via, for example, a transceiver. The transceiver may include a transmitter 906 and receiver 908. In some embodiments, controller 904 may control the image signal process of detection system 900.

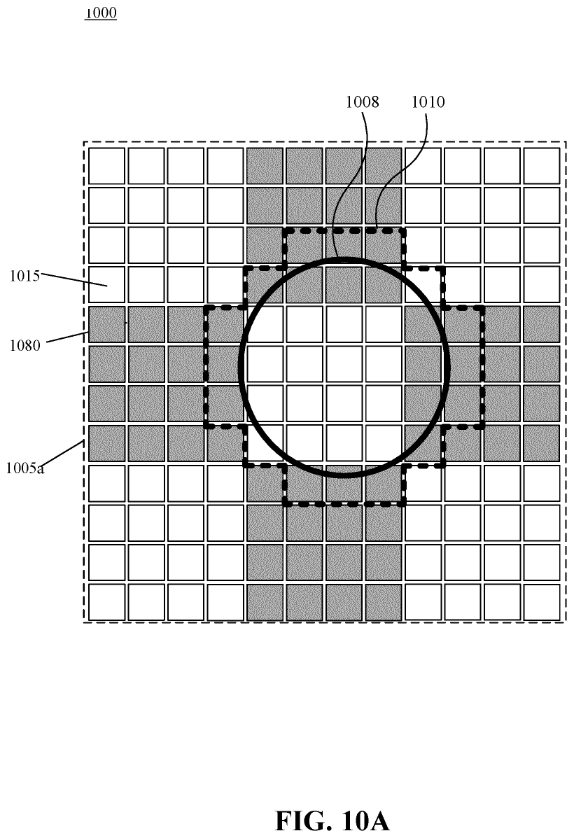

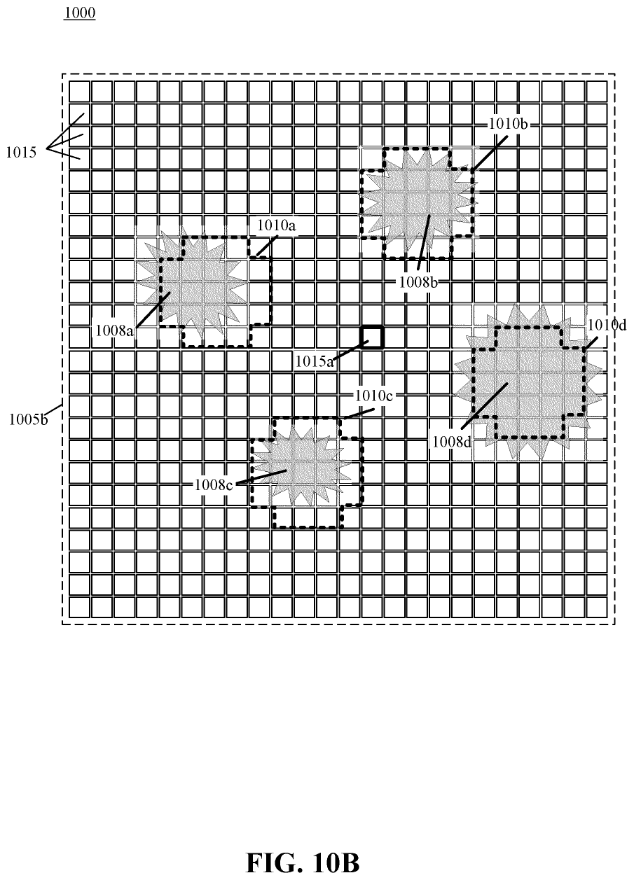

FIG. 10A illustrates a detector 1000 surface and picture mode operation according to some embodiments of the present disclosure. Detector 1000 may correspond to a detection surface of charged-particle detection device 244 of FIG. 2 or any of the detectors as described with reference to FIGS. 3A-9. The detection surface may comprise an array of sensing elements, such as PIN diode elements. In some embodiments, sensing elements may include, e.g., an avalanche diode, an electron multiplier tube (EMT), or other components. Each of the sensing elements (e.g., PIN diodes) may correspond to a discrete sensing element 1015. Alternatively, a single sensing element (e.g., a PIN diode) may be pixelated into separate sensing elements 1015 in various ways. For example, semiconductor detection cells may be divided by virtue of internal fields generated due to internal structures. In some embodiments, there may be physical separation between adjacent sensing elements, such as by area 1080 provided between adjacent sensing elements. Area 1080 may be an isolation area to isolate the sides or corners of neighboring sensing elements from one another. In some embodiments, area 1080 may include an insulating material that is different from that of the sensing elements 1015 on the sensor surface of detector 1000. In some embodiments, area 1080 may be provided as a square. In some embodiments, area 1080 may not be provided between adjacent sides of sensing elements.

As shown in FIG. 10A, there may be a region of interest 1005a on surface of detector 1000. A pixelated array of sensing elements on a detector may make up region of interest 1005a. In some embodiments, detector 1000 may be implemented in a single-beam system. In some embodiments, detector 1000 may be implemented in a multi-beam system. In some embodiments there may be more sensing elements provided in the detector outside of the depicted region of interest 1005a (such as region 1005b in FIG. 10B). As illustrated by the light and dark areas in FIG. 10A, sensing elements 1015 may be functionally divided into sections of, e.g. 4×4 arrays, such as section 321 of FIG. 4. A secondary beam spot 1008 may be formed on the surface of the detector 1000. Beam spot 1008 may have a well-defined center, or locus. Although beam spot 1008 is illustrated as having an approximately round shape, a distribution of secondary particles landing within beam spot 1008 may have an irregular shape and may deviate substantially from a round shape (e.g., such as beam spots 1008a-d in FIG. 10B). Furthermore, the distribution of particles received within beam spot 1008 may follow various patterns or may be random. Typically, particles are not distributed in a Gaussian pattern within a beam spot. Still, some regions of beam spot 1008 may receive more secondary particles than others. Secondary particles may be generated in response to incidence of a primary beam on a sample and may be emitted with a variety of energy and emission angles. The secondary particles may form a beam (e.g., a secondary electron beam). The secondary electron beam may be incident on the detector and may form beam spot 1008.

A picture-mode operation of charged particle beam apparatus and charged particle detector (sometimes referred to as a charged particle beam detector) may be used to obtain a high-resolution image of beam spot 1008 on detector 1000, which may indicate beam spot parameters such as size, shape, and intensity distribution. It may also indicate conditions of the beam such as alignment, divergence, incidence angle upon a sample surface, etc., as well as further conditions of the charged particle beam apparatus and its various components. These parameters and conditions may be used for, e.g. an alignment, tuning or other maintenance process of the charged particle beam apparatus. The high-resolution picture mode image may also be used to determine an appropriate grouping of sensing elements 1015 for use in a further “beam mode” operation. In beam mode, a collection of sensing elements may be coupled to a common signal readout path, such as via inter-element switching elements or element-bus switching elements (not shown in FIG. 10A), to collect secondary particle detection signals of beam spot 1008. Meanwhile, adjacent sensing elements 1015 outside the group may be disconnected from the signal readout path to improve parasitic parameters, and to prevent unwanted signals such as thermal noise and cross-talk from neighboring beams. Therefore, an ideal grouping of sensing elements 1015 may include those sensing elements 1015 that receive a substantial amount of charged particles from beam spot 1008 and exclude those that do not.

Using a picture mode image, a boundary 1010 may be determined. Boundary 1010 may be provided so as to encompass sensing elements that receive charged particles from the secondary electron beam. The sensing elements contained within boundary 1010 may be covered, at least partially, by the same charged particle beam spot 1008. Boundary 1010 may include a border of beam spot 1008. As used herein, the term “boundary” may refer to an outer perimeter encompassing a beam spot as encoded by a detector. The shape of the boundary may conform to the shapes of individual sensing elements 1015. A “border” may refer to an outline of a beam spot. The border of beam spot 1008 may more closely correspond to a natural shape formed by charged particles of a beam impinging on a surface. For example, a beam spot may have an approximately round border and a more square boundary surrounding the border. In some embodiments, the border and boundary may coincide.

Determination of a beam spot boundary 1010 may be based on an acquired beam spot projection pattern. A beam spot projection pattern may be acquired by successively reading individual outputs of each sensing element that may be included in a detector. In some embodiments, boundary 1010 may be determined by image processing of the high-resolution picture mode image. In picture mode, an image of the detector surface may be acquired, and a boundary 1010 or grouping of sensing elements associated with a beam spot 1008 may be determined. Note that because a grouping of sensing elements is identified by reference to this imaginary boundary, like numerals may interchangeably refer to the group of sensing elements or the boundary that encompasses the group. During picture mode, a detection system may be dedicated to projection pattern acquisition. It may be determined, for example, that electrons are being received in a group of sensing elements 1015 on the surface of detector 1000. The group of sensing elements may be continuous and may have a substantially round shape. Boundary 1010 may be drawn around the sensing elements in the group. Each of the sensing elements within the boundary may be receiving electrons at least partially within the surface area of the sensing element. Sensing elements included in the group may be used for later processing, such as beam spot intensity determination (e.g., using beam mode). Other processing in picture mode may include pattern recognition, edge extraction, etc.

In some embodiments, beam spot 1008 may deviate from a round shape in a variety of ways. For example, beam spot 1008 may have an elongated shape, or an irregular shape such as a starburst. Additionally, the border of a beam spot does not necessarily represent a full spatial extent of secondary particles associated with that beam spot. Rather, the border may indicate an area within which a threshold concentration of secondary particles may be found. For example, an actual distribution of secondary particles may taper off gradually in the radial direction from a central portion of beam spot 1008 and extend out to an area beyond the border of beam spot 1008 and boundary 1010. These outer secondary particles may be disregarded from the beam spot because, e.g., their concentration is too low to make their collection worthwhile. For example, the potential increase in collection efficiency from collecting the secondary particles may be outweighed by the risk of cross talk from neighboring beams. Therefore, the grouping of sensing elements 1015 within boundary 1010 may include only those sensing elements 1015 that receive a substantial amount of charged particles from beam spot 1008. In some embodiments, the grouping of sensing elements 1015 may include only those sensing elements 1015 that receive more than a predetermined amount of irradiation. The predetermined amount may be set by experiment, simulation, operator preference, or any other parameter that may be configured in advance or on-the-fly.

After boundary 1010 is determined for a beam spot in picture mode, sensing elements within the boundary may be grouped together during a beam mode operation, such as a SEM inspection or other charged particle beam process. The grouped elements may be functionally coupled to a common signal readout path, such as via inter-element switching elements, element-bus switching elements, or interconnection switching elements as discussed with respect to FIG. 4 (not shown in FIG. 10A). Measurements at the grouped sensing elements within boundary 1010 are determined to correspond to measurements of secondary beam spot 1008. Further details of picture mode and beam mode operations may be found in U.S. Provisional Application No. 63/130,576, the entirety of which is incorporated herein by reference.

As discussed above with respect to FIG. 4, there may be many ways to configure a signal readout path in detector 1000. For example, if detector 1000 is implemented in a single-beam system, every sensing element may be coupled to a signal readout path via element bus switching elements, such as 316 in FIG. 4. There may be no need to use, or even include, inter-element switching elements 315 or an interconnection layer 416. Sensing elements that are not grouped with the single beam may be disconnected to reduce parasitic parameters in the detector. If the detector 1000 is implemented in a multi-beam system, an optimal configuration of signal readout paths may be determined that can differentiate each beam while minimizing parasitic parameters.

During use of a charged particle beam apparatus, beam spot parameters may drift and change. For example, a beam spot may change shape, its centroid location on a detector may shift, or its overall size may increase or decrease. These changes may be difficult to predict, especially when the beam shape does not resemble the idealized circle of FIG. 10A. If beam spot 1008 changes its shape, size, location, or other parameter, the boundary 1010 may no longer coincide with the actual sensing elements 1015 that receive secondary particles. This mismatch presents two issues. First, there is a loss of measured beam intensity because some sensing elements that receive the secondary particles of the beam are not coupled to the group of sensing elements located within boundary 1010. Thus, any secondary particles received by these ungrouped sensing elements may not be recorded. Second, other sensing elements that are coupled to the group may not be receiving secondary particles, and so they may provide no useful information. These other sensing elements may serve only to increase parasitic parameters, reduce data processing speed and analog signal bandwidth, or may have other detrimental effects.

FIG. 10B illustrates the detector 1000 of FIG. 10A, consistent with some embodiments of the present disclosure. Here, a region 1005b is shown which may be larger than region of interest 1005a of FIG. 10A. In some embodiments of the present disclosure, region 1005b may encompass an entire surface of detector 1000. Four beam spots 1008a-d are incident on distinct portions of region 1005b of detector 1000. Here, a 2×2 array of beam spots is depicted, but any suitable arrangement of beam spots is contemplated in some embodiments of the present disclosure. For instance, beam spots 1008 may be arranged in a 3×3, 5×5, 2×10 array, or any other permutation. The beam spots may have a more complex or irregular arrangement. Beam spots 1008a-d are each incident upon a different portion of detector 1000. Each beam spot 1008a-d has been assigned a grouping of sensing elements 1015 circumscribed by boundaries 1010a-d. Each beam spot 1008a-d overlaps, but is not coextensive with, its grouping boundary 1010a-d. It is noted that while boundaries 1010a-d are depicted as identical in FIG. 10B, this need not be the case. Each boundary 1010 may be determined independently to fit each beam spot 1008, e.g., according to a picture mode imaging operation. However, due to subsequent drift, or due to an initial picture mode process that yields sub-optimal results, boundaries 1010a-d may not align well with beam spots 1008a-d. Boundaries may be initialized based on a rough estimate, and may be refined by iterative tuning.

For example, beam spot 1008a has an area that is approximately equal to boundary 1010a, but its position is laterally offset and the shapes are mismatched. This results in sensing elements outside boundary 1010a that receive secondary particles, and sensing elements inside boundary 1010a that do not. The secondary particles received by sensing elements outside the boundary 1010a will not be recorded, and the grouped sensing elements inside the boundary that are not receiving secondary particles may serve only to degrade performance of the detector. On the other hand, beam spot 1008b is roughly equal in size, shape and location to its boundary 1010b. There may be no sensing elements that should be added to, or removed from, the group of sensing elements within boundary 1010b. Beam spots 1008c and 1008d are both substantially aligned with their respective boundaries 1010c and 1010d. However, beam spot 1008c has a smaller area than boundary 1010c. This results in unused sensing elements along the bottom portion of the group as viewed in FIG. 10B. Finally, beam spot 1008d is larger than boundary 1010d. Therefore, the group of sensing elements within boundary 1010d fails to capture every usable sensing element receiving secondary particles, resulting in a loss of intensity.

It may be possible to determine a new boundary 1010 that corresponds to the new shape, and a new grouping of sensing elements associated with the modified beam spot 1008 may be updated accordingly. However, in comparative embodiments this requires a new picture mode imaging operation to be performed, which may lead to increased downtime and reduced throughput of the charged particle beam apparatus. It is desirable for the detector to be able to automatically update a grouping of sensing elements 1015 in real time. Updating may include coupling previously ungrouped sensing elements (adding) or decoupling previously grouped sensing elements (removing). For instance, a previously ungrouped sensing element 1015 may be added if it is receiving secondary particles above a first threshold level indicating that a portion of a beam spot 1008 is incident on the sensing element. A previously grouped sensing element 1015 may be removed if it is receiving secondary particles below a second threshold level indicating that no substantial portion of the beam spot 1008 is incident on the sensing element.

Achieving such a function with high speed and accuracy may pose some challenges. One challenge may be a lack of uniquely identifiable intensity readings from individual sensing elements during a beam mode operation. This is because sensing elements may either be grouped together in a signal readout path, rendering their signals indistinguishable, or decoupled from the signal readout path entirely, potentially making them unreadable. Therefore, in a comparative sensing architecture, it may be difficult to determine which sensing elements should be added to, or removed from, a group. Another challenge is determining whether a new sensing element's signal should be associated with a particular beam spot of a particular group. For instance, sensing element 1015a in FIG. 10B is located roughly equidistant from each of the beam spots 1008a-d. Even if it can be determined that sensing element 1015a is receiving secondary particles above a certain threshold, one would still need to determine the group of sensing elements, if any, to which it should be assigned.

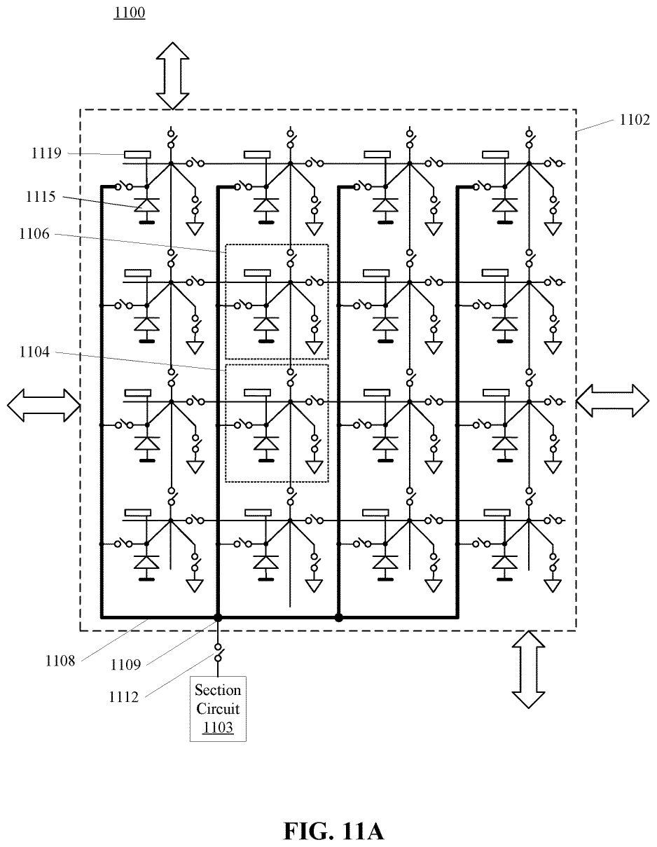

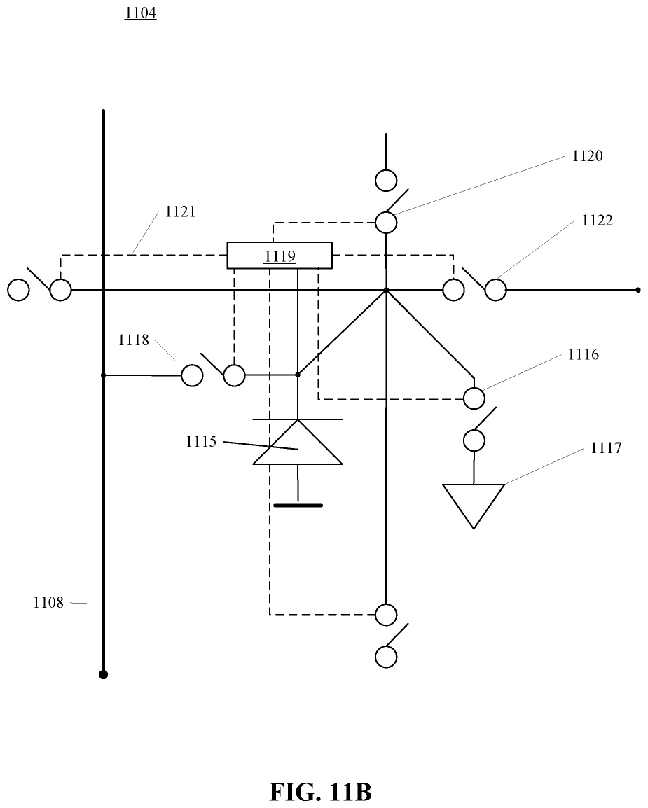

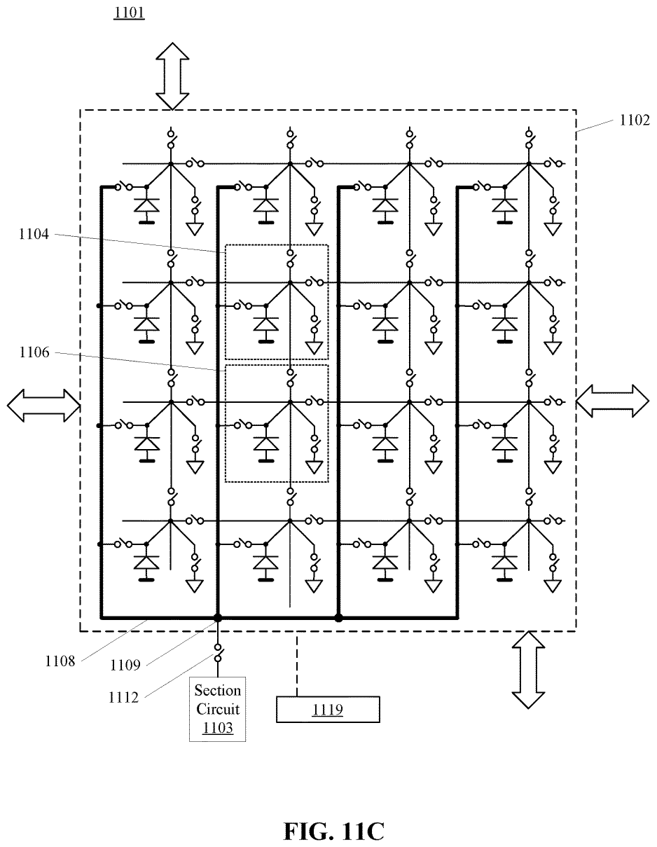

FIG. 11A is a diagrammatic representation of a 4×4 section 1102 of sensing elements 1115 in a detector array 1100 that may alleviate some of the issues discussed above, consistent with embodiments of the present disclosure. FIG. 11B is a diagrammatic representation of one such sensing element 1115 in the detector array 1100, consistent with embodiments of the present disclosure. Detector array 1100 may be an example embodiment of, e.g., any of the detectors described with respect to FIGS. 2-10B. The switch matrix design of FIG. 11A may be used in either a single-beam inspection tool or a multibeam inspection tool (e.g., beam tool 114 in FIG. 2). The switch matrix may comprise a plurality of transistors as the switching elements as discussed above with respect to FIGS. 5-6. Each sensing element 1115 in the switch matrix design may include a threshold circuit 1119 that allows a switching element to be locally actuated based on a locally detected parameter.

In FIG. 11A, detector array 1100 may include multiple sections (e.g., sections similar to section 321 in FIG. 3B etc.), including section 1102 (enclosed by a dash-line box). Section 1102 may be communicatively coupled to one or more other sections of detector array 1100. In FIG. 11A, section 1102 is communicatively coupled to four adjacent (or neighboring) sections (not shown in FIG. 11A) in its four planar directions (shown by double-headed arrows). Two adjacent objects along a direction herein may refer to two objects that have no intervening object arranged therebetween along the direction. Such object may be, for example, a section 1102 or a sensing element 1115.

Each sensing element of detector array 1100 may have substantially the same structure and operate in substantially the same way. In FIG. 11A, sensing element circuits 1104 and 1106 (e.g., a unit cell comprising a sensing element and associated switching elements and other circuitry) are adjacent in the vertical (e.g., y-axis) direction. Section 1102 further includes an output bus 1108 (shown as bold-black lines) that is a shared signal bus for receiving individual detection signals generated by the sensing elements (e.g., at sensing element circuits 1104 or 1106). Output bus 1108 may output the received signals independently via a bus output 1109 to a section signal path or read out circuit. As shown in FIG. 11A, output bus 1108 may output signals to a section circuit 1103. Section circuit 1103 may, for example, be included in any of sections 321-324 in FIG. 3A. A switching element 1112 may be arranged between bus output 1109 and section circuit 1103. In some embodiments, when no signal is output at bus output 1109, switching element 1112 may be set as communicatively disconnected (e.g., open) for reducing parasitic parameters in signal processing.

FIG. 11B is a diagram illustrating one sensing element circuit 1104 of section 1102 in FIG. 11A, consistent with embodiments of the present disclosure. Sensing elements of a detector array may generate signals in response to incidence of incoming charged particles. Thus, a sensing element may act as a diode in that it may convert incident energy into a measurable signal, and may do so in predetermined directions. A sensing element (diode) 1115 may be configured to convert a charged particle landing event into an electrical signal. Sensing element 1115 may be conceptualized as including a diode or other electrical components. As shown in FIG. 11B, sensing element circuit 1104 includes a diode 1115, a grounding switching element 1116, a grounding circuit 1117, an element-bus switching element 1118, and inter-element switching elements 1120 and 1122 (further inter-element switching elements are not labeled in FIG. 11B). For example, in sensing element circuit 1104, diode 1115 may convert energy of incident charged particles into a measurable electrical signal (e.g., current). For example, diode 1115 may be a PIN diode, an avalanche diode, an electron multiplier tube (EMT), or the like. Grounding switching element 1116 may connect sensing element circuit 1104 to grounding circuit 1117. A grounding circuit may be used to release charges from a sensing element that is not in use. In some situations, sensing elements that are not in use may still receive charged particles exiting a wafer, for example when a sensing element is disconnected to reduce cross talk, noise, or parasitic parameters. If a sensing element is used for charged particle beam detection, grounding switching element 1116 may be kept communicatively disconnected (e.g., open). If a sensing element is not in use, the grounding switching element may be set as communicatively connected (e.g., closed). Element-bus switching element 1118 may communicatively couple diode 1115 to output bus 1108 for detection signal outputting. Inter-element switching elements 1120 and 1122 may communicatively couple sensing element circuit 1104 to its adjacent sensing elements in horizontal (e.g., x-axis) and vertical (e.g., y-axis) directions, respectively. For example, when being communicatively connected (e.g., closed), inter-element switching element 1120 may communicatively couple sensing element circuit 1104 to sensing element circuit 1106. Similar components of sensing element circuit 1106 may function in a similar way to corresponding components of sensing element circuit 1104.

In some embodiments, the element-bus switching elements (e.g., element-bus switching element 1118) of sensing element circuit 1104 may be independently controlled (e.g., by controller 109 or image processing system 290 of FIGS. 1 and 2 respectively, or by controller 904 in FIG. 9) for signal output. Additional details of discussion of sensing element components may be found in International Publication No. WO 2021/239754 A1, the entirety of which is incorporated herein by reference.

Sensing element circuit 1104 may further comprise a threshold circuit 1119 configured to actuate a switching element in sensing element circuit 1104. For example, threshold circuit 1119 may comprise one or more transistors configured to pass charge from diode 1115 to one of the switching elements (such as switching elements 1116, 1118, 1120 or 1122). When current is produced (or charge is accumulated) at diode 1115, at least a portion of the current may be diverted to threshold circuit 1119 for determining the current level locally. The current may relate to the quantity, rate or character of secondary particles landing at the sensing surface of sensing element 1115. Threshold circuit 1119 may comprise a comparator or other element configured to compare the measured current to a reference (e.g., one or more thresholds). Threshold circuit 1119 may be further configured to send actuation signals via signal lines 1121 (illustrated in dashed lines) to actuate a switching element of sensing element circuit 1104 based on the measurement or comparison. In some embodiments of the present disclosure, individual switching elements may be coupled to a dedicated threshold circuit 1119. In some embodiments of the present disclosure, a single threshold circuit 1119 may be coupled to multiple switching elements. In some embodiments of the present disclosure, the switching element and threshold circuit may be considered a single element. In this case, the sending of actuation signals may refer to passing current directly from diode 1115 through threshold circuit 1119 as the switching element and into, e.g., a signal readout path of a group of sensing elements 1115. In some embodiments of the present disclosure, threshold circuit 1119 may act on a switching element to open or close the switching element, allowing other current from diode 1115 to pass through the switching element. The sending of actuation signals may refer to driving a switching element by the threshold circuit 1119 so that the switching element passes current from diode 1115. In this way, threshold circuit 1119 may act locally to both detect a parameter of the sensing element and actuate a switching element based on the detected parameter. In some embodiments, one or more of the sensing, threshold setting, comparing, or switch actuation may be controlled or initiated at the sensor level (e.g., by threshold circuit 1119), at the detector level (e.g., by controller 904) or at the apparatus level (e.g., by controller 109 or image processing system 290). The threshold circuits 1119 allow determination of a local value of secondary particle landing events at each sensing element 1115. In some embodiments of the present disclosure, this determination may be made during a beam mode operation even when the sensing element is grouped with other sensing elements inside a boundary (such as 1010 of FIGS. 10A-B) or when the element is outside the boundary and isolated from the grouped sensing elements.

In some embodiments of the present disclosure, a threshold circuit 1119 may be idle unless activated. For example, the threshold circuit may be activated when its associated sensing element is a candidate for adding to, or removing from, a group of sensing elements. Candidacy may be established by proximity of the sensing element to a boundary of the group. Conditioning the activation on such proximity may ensure that changes to a group boundary are gradual and continuous. This may enable the group to accurately track a continuously shifting beam spot when real-time information about the beam spot shape is limited. It may also be a rapid and efficient manner of determining that a sensing element should be associated with a nearby beam spot rather than one farther away. Proximity may be determined, e.g., by locally stored digital information (e.g., stored at sensing element circuit 1104 or controller 904) about the switching status of neighboring sensing elements. For instance, an ungrouped sensing element may be determined to be a candidate for adding to a group if at least one of its neighboring sensing elements is connected to the group by at least one closed switching element. As another example, a grouped sensing element may be determined to be a candidate for removing from the group if at least one of its neighboring sensing elements is not connected to the group. In this way, the threshold circuit 1119 may be used in conjunction with digital information about the switching state of other elements 1115 in detector array 1100 to dynamically adjust a beam spot boundary during a beam mode operation, as further discussed below.

FIG. 11C illustrates an alternative configuration to that shown in FIGS. 11A-B, consistent with embodiments of the present disclosure. Instead of providing dedicated threshold circuits 1119 at each sensing element 1115, some embodiments provide a single threshold circuit 1119 that may receive signals from multiple sensing elements. As illustrated in FIG. 11C, a single threshold circuit may serve an entire section 1102. Alternatively, a single threshold circuit 1119 may serve, e.g., two or four sensing elements within a section, multiple entire sections, or the entire detector. An additional switch matrix (not shown) may be provided for routing signals from sensing elements 1115 to threshold circuit 1119. In this way a single threshold circuit 1119 may perform thresholding to multiple sensing elements. For example, the threshold circuit may comprise a large number of parallel comparator architectures configured to perform multiple thresholding operations simultaneously. In some embodiments of the present disclosure, only a portion of sensing elements will undergo a thresholding operation at any given time. A centralized threshold circuit 1119 may advantageously reduce the total number of thresholding components required in the detector. Threshold circuit 1119 may form part of, e.g., controller 109 or image processing system 290 of FIGS. 1 and 2 respectively, controller 904 in FIG. 9, or another portion of the detector processing circuitry.

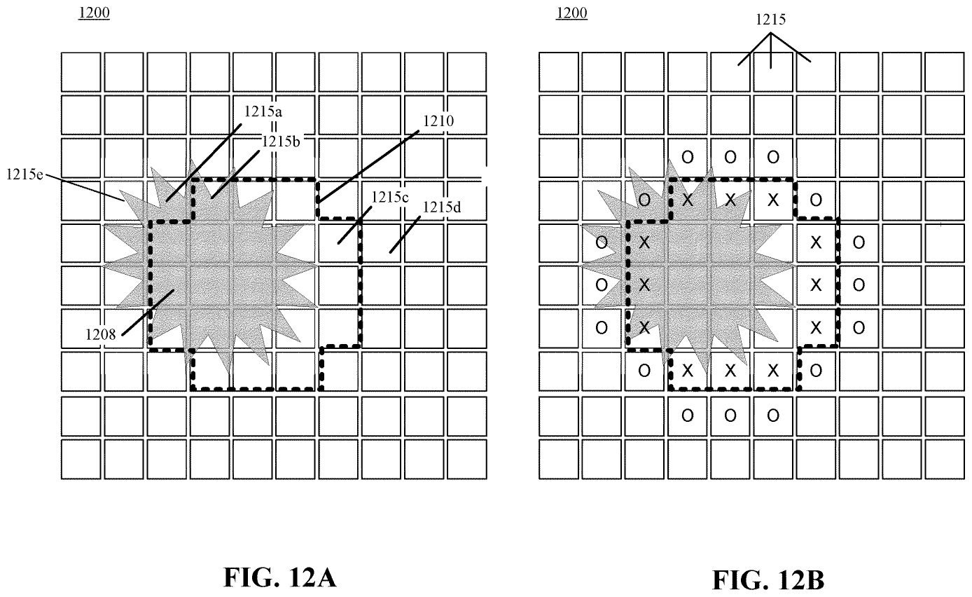

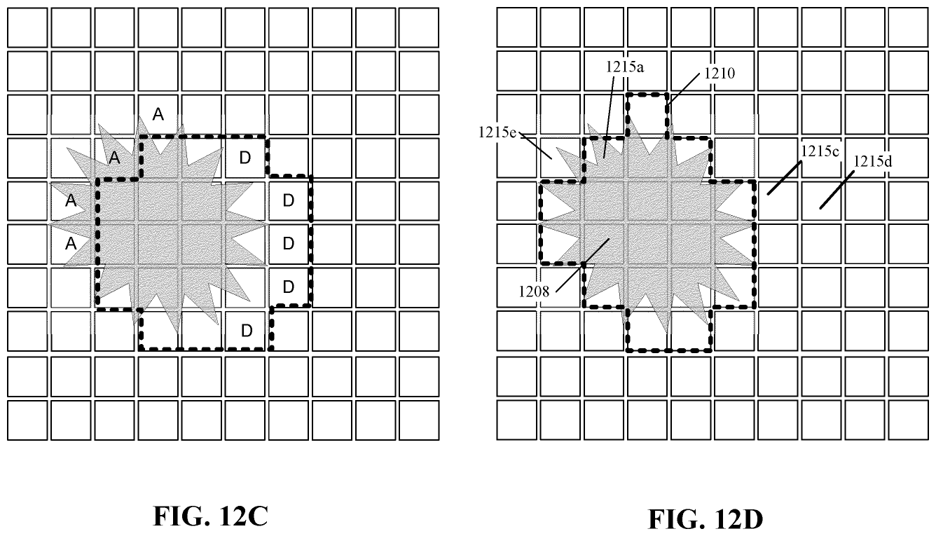

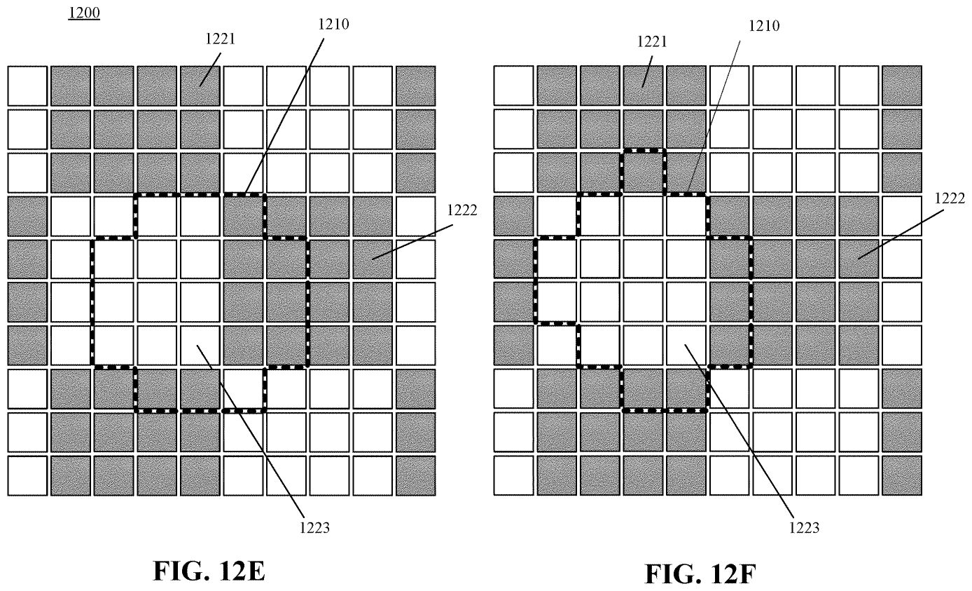

FIGS. 12A-D illustrate an example of a dynamic beam spot boundary adjustment process on a portion of a detector 1200, consistent with embodiments of the present disclosure. Detector 1200 may be, e.g., an example embodiment of any of the detectors of FIGS. 2-11B. Sensing elements 1215 of detector 1200 may comprise circuit elements described in FIGS. 11A-B. For example, in some embodiments of the present disclosure, sensing elements 1215 may comprise a diode 1115, switching elements 1116/1118/1120/1122 connected to the diode, a threshold circuit 1119 connected to the diode and signal lines 1121 connected to the switching elements, etc.

In FIG. 12A, beam spot 1208 overlaps, but is mismatched from, its assigned group of sensing elements within boundary 1210. The mismatch may be similar to the mismatch shown between beam spot 1008a and boundary 1010a in FIG. 10B. Beam spot 1208 may be one of an array of beam spots formed on detector 1200 surface during, e.g., a beam mode operation. During the beam mode operation, boundary 1210 may be periodically or continuously updated by the dynamic beam spot boundary adjustment.

Initially, a sensing element 1215 is determined to be a candidate for updating. Here updating may comprise adding the candidate to the group (e.g., within boundary 1210) of sensing elements (such as 1215a/d) or removing the candidate from the group of sensing elements (such as 1215b/c). In some embodiments of the present disclosure, a plurality of such candidates may be identified substantially simultaneously (e.g., within the same clock cycle of a processor, or within a few clock cycles, such as 10's or 100's of cycles) and multiple updating processes may be carried out substantially in parallel. Candidacy may be established by determining proximity of the candidate sensing element 1215 to boundary 1210 of the group. This may be accomplished using digital information about the switching state of elements or other grouping information. For example, there may be accessible digital information showing that sensing element 1215b is grouped within the boundary 1210, in part because one or more of its inter-element switching elements or element-bus switching elements (not shown) are closed to connect sensing element 1215b to the group. Furthermore, there may be accessible digital information showing that adjacent sensing element 1215a is not grouped within the boundary 1210, in part because its switching elements may be open. Because a grouped sensing element is directly adjacent to a non-grouped sensing element, both are determined to be in proximity to a boundary 1210 and are identified as candidates 1215. The same is true for sensing elements 1215c-d. Grouping information may take other forms. But relying on switching status may be one way to allow a detector 1200 to rapidly process information about the state of adjacent sensing elements.

As depicted in FIG. 12A, proximity may refer to two sensing elements being directly adjacent to each other, such as sensing elements 1215a-b. However, in some embodiments of the present disclosure, proximity may refer to two sensing elements being located within a prescribed number of sensing elements, or any other suitable measure of proximity. For example, proximity may be determined based on the location of sensing elements within a defined region of a detector surface. When a non-adjacent sensing element is identified as a candidate, a subsequent adding or removing step may or may not comprise adding or removing any intervening sensing elements. Furthermore, a diagonally adjacent sensing element may be considered adjacent even when, as seen in FIG. 11A, a switch matrix is not configured with diagonal inter-element switching elements. In some embodiments of the present disclosure, sensing elements may only be considered adjacent when they share a common inter-element switching element. In some embodiments of the present disclosure, diagonal inter-element switching elements may be present in a switch matrix.

In some embodiments, candidacy may not be determined by proximity at all, but instead by another suitable grouping parameter. For example, sensing elements may be deemed candidates for adding/removing by reference to a model of beam spot shapes, to historical information of a progression of the beam spot shapes, etc. In some embodiments of the present disclosure, a determination of candidacy may be eliminated entirely or performed in another order. For example, rather than activating a threshold circuit (such as 1119) based on some candidacy parameter, a sensing element may be continuously monitoring its current by a threshold circuit, and an adding or removing action may be determined only after a threshold level is crossed. In this case, adding a sensing element may include deciding the group to which the sensing element should be added.

In FIG. 12A, a plurality of exemplary sensing elements 1215a-e are illustrated. According to the process discussed below (and suggested by the beam spot 1208 overlap): sensing element 1215a is an example of an ungrouped sensing element that will become added to the group; sensing element 1215b is an example of a grouped sensing element that will remain in the group; sensing element 1215c is an example of a grouped sensing element that will be removed from the group; and sensing element 1215d is an example of an ungrouped sensing element that will remain out of the group. Sensing element 1215e is not presently a candidate in the embodiment of FIG. 12A despite some beam spot overlap. However, if adjacent sensing element 1215a becomes grouped, then sensing element 1215e may become a candidate and be added to the group in a subsequent updating cycle.

FIG. 12B illustrates each sensing element that may be identified as a candidate in an example embodiment of detector 1200 of FIG. 12A, consistent with embodiments of the present disclosure. In this embodiment, every sensing element that is horizontally or vertically (i.e. not diagonally due to lack of diagonal switching elements in the present example embodiment) adjacent to boundary 1210 is identified as a candidate. Sensing elements marked “X” in the figure are grouped sensing elements identified as candidates for being removed from the group. Sensing elements marked “O” in the figure are ungrouped sensing elements identified as candidates for being added to the group. Note that in the embodiment of FIG. 12B, each candidate for adding to the group is adjacent a candidate for removing from the group, and vice versa. In some embodiments of the present disclosure, candidacy of a sensing element may be established when a neighboring sensing element has a different grouping status. For example, a sensing element may be a candidate for adding to a group if one of its neighboring sensing elements is already a member of the group. A sensing element may be a candidate for removing from a group if one of its neighboring sensing elements is not a member of the group. Each of the candidate sensing elements may be coupled to a threshold circuit (not shown) which is activated to measure current generated at the sensing element from beam spot 1208. The threshold circuit may be configured to compare the measurement to a certain threshold.

Ungrouped sensing elements O may be added if the sensing elements are receiving a substantial amount of secondary particles from beam spot 1208. Therefore, the current measured at ungrouped sensing elements O may be compared to a first threshold, and may be added to the group of sensing elements within boundary 1210 if the sensing elements O exceed the first threshold. Grouped sensing elements X may be removed if the sensing elements are not receiving sufficient secondary particles from beam spot 1208 to justify their presence in the group. Therefore, the current measured at grouped sensing elements X may be compared to a second threshold and may be removed from the group if the sensing elements X fall below the second threshold. In some embodiments of the present disclosure, the first and second thresholds may be the same. In some embodiments of the present disclosure, the first and second thresholds may be different. For instance, the first threshold may be higher than the second threshold. In some embodiments of the present disclosure in which non-adjacent sensing elements may be candidates, a third threshold may be set for additional candidate elements that are farther away from boundary 1210. For instance, an ungrouped candidate sensing element that is, e.g., displaced from boundary 1210 by three sensing elements may be compared to the third threshold that is higher than the first threshold, and may be added only if the current from the farther sensing element exceeds this higher threshold.

FIG. 12C illustrates an example embodiment of FIGS. 12A-B, consistent with some embodiments of the present disclosure. Here, sensing elements marked “A” are candidate elements that were added to the group. This may be because a threshold circuit at each sensing element A received a current that exceeded the first threshold. As a result, one or more switching elements in each sensing element A that were previously open may be closed to pass the current from the sensing element to a signal readout path of the group. Additionally, a grounding switching element (such as 1116 in FIG. 11B) may be opened by the threshold circuit or another control signal (such as, e.g., controller 904).

Sensing elements marked “D” are candidate elements that were removed from the group. This may be because a threshold circuit at each sensing element received a current that fell below the second threshold, or received no current. As a result, any switching elements in sensing elements D that were previously closed to connect sensing elements D to a signal readout path of the group may be opened to decouple parasitic parameters of the sensing elements D from the group. Additionally, a grounding switching element (such as 1116 in FIG. 11B) may be closed by the threshold circuit or another control signal (such as, e.g., controller 904). The switching status of each of these elements may be updated accordingly so that new digital information about the new status of the switching elements is available.

Finally, FIG. 12D illustrates an updated boundary 1210 of the element group. Boundary 1210 as updated conforms more closely to the shape and location of beam spot 1208. The result is a group of sensing elements that maximizes capture of secondary particles from beam spot 1208 while minimizing parasitic parameters from unused sensing elements.

FIG. 12D also illustrates what may happen to some sensing elements as an updated boundary 1210 moves either toward or away from the sensing elements. For example, as discussed above, sensing element 1215e was receiving secondary particles in FIGS. 12A-B but was not identified as a candidate, and therefore was not subjected to a thresholding operation or added to the group. However, in FIG. 12D, sensing element 1215e is now adjacent to the updated boundary 1210 via newly grouped sensing element 1215a. Sensing element 1215e may therefore be identified as a candidate and subsequently added to the group in a second cycle of the updating process. Because the threshold circuit may automatically sense the current and actuate a switching element based on analog signals, the updating process may occur in rapid cycles with only minimal action required from centralized signal processing circuitry. Thus even a multi-step updating process, such as the successive addition of sensing elements 1215a and 1215e in FIGS. 12A-D, may occur with sufficient speed to easily track the changes in a charged particle beam spot 1208 on detector 1200.

As another example, FIG. 12D illustrates how a thresholding operation within a sensing element may end without any change to the switching status of the sensing element. Previously grouped sensing element 1215c has been removed from the group, which alters the proximity status of sensing element 1215d. Because sensing element 1215d is no longer adjacent to a boundary 1210 of the group, it may no longer be identified as a candidate in this exemplary embodiment. Based on new switching status information of sensing element 1215c, a controller (such as controller 904 of FIG. 9, controller 109 of FIG. 1 or image processing system 290 of FIG. 2), may terminate the thresholding operation at sensing element 1215d. Sensing element 1215d may then revert to an ordinary off state.

FIG. 12E and F illustrate how the process in FIGS. 12A-D may change the parameters that determine the optimal configuration of signal routing paths in the switch matrix. FIG. 12E and F illustrate boundary 1210 of the grouping of sensing elements at the times shown in FIG. 12C and D respectively. Beam spot 1208 is omitted for clarity. As shown by light and dark regions, sensing elements may be functionally divided into sections of, e.g. 4×4 arrays, such as section 321 of FIG. 4. Additionally, as discussed above with respect to FIG. 4, there may be many ways to configure a signal readout path in detector 1200. For example, when the boundary 1210 around the grouping of sensing elements shifts from the configuration of FIG. 12E to that of FIG. 12F, section 1221 begins to contribute a single sensing element to the grouping, whereas before it contributed none. This single sensing element may be added by, e.g., closing the inter-element switching element that connects the single sensing element to an adjacent sensing element in central section 1223.

However, section 1222 changes more drastically. Section 1222 goes from initially contributing seven sensing elements in FIG. 12E to contributing only three in FIG. 12F. In the initial configuration, for example, section 1222 may be coupled to section 1223 via interconnection switching elements in an interconnection layer, with each of the seven sensing elements being coupled to the interconnection layer by their respective element-bus switching elements. In some embodiments, when changing to the configuration of FIG. 12F, each sensing element may perform an independent thresholding operation within its own threshold circuit, and act independently of the other threshold circuits of other sensing elements. This may result in each thresholding circuit within the four dropped sensing elements of section 1222 removing its respective sensing element by opening the corresponding element-bus switching element. However, the resulting arrangement may not yield the optimal switching configuration in terms of parasitic parameters. It may be more advantageous to, e.g., disconnect the entire analog signal path of section 1222 and couple the remaining three sensing elements to section 1223 by their inter-element switching elements.

In some embodiments of the present disclosure, a controller may be configured to determine the optimal switching configuration concurrently with the thresholding operation, so that the optimal switching configuration is selected in real time during the transition from FIG. 12E to FIG. 12F. For example, a controller may determine, from a set of candidates that are presently undergoing a thresholding operation, a set of configurations that may be implemented for a given set of candidates satisfying their respective threshold. A set of configuration templates may be stored, e.g. in a lookup table for this purpose.

In some embodiments of the present disclosure, the switching may occur in multiple stages. In a first stage, the thresholding operation may actuate a switch to immediately add or remove a sensing element to or from a grouping. For instance, thresholding circuits may actuate element bus switching elements in section 1222 to remove the four sensing elements from the group, and actuate an inter-element switching element to add the single sensing element from section 1221. In a second stage, a controller (e.g., controller 109 or image processing system 290 of FIGS. 1 and 2 respectively, or controller 904 in FIG. 9) may determine whether the switching configuration accomplished during one or more of the switching operations above yields the optimal configuration. This determination may be performed periodically in time, with every actuation of the switch matrix, or after a prescribed number of switches have been made, etc. If the controller determines that a better configuration of the switch matrix exists, the controller may actuate the appropriate switches to achieve the better configuration.

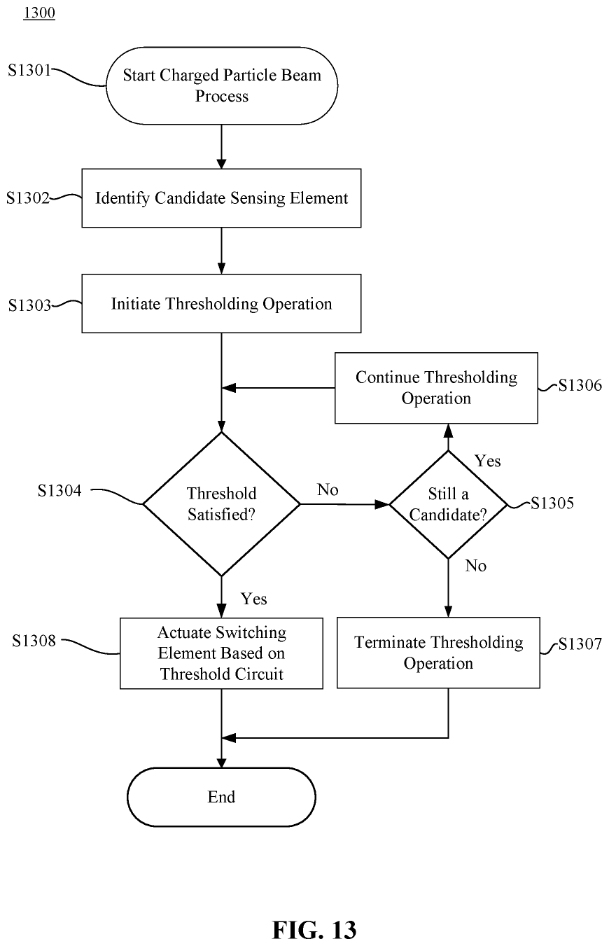

FIG. 13 illustrates a flowchart of an exemplary method of dynamically updating switching elements in a switch matrix of a detector, consistent with embodiments of the present disclosure. The detector may be, e.g., any of the charged particle detectors disclosed with respect to FIGS. 2-12D. The detector may be part of an apparatus such as beam tool 104 of FIGS. 1-2. The detector may comprise a plurality of individual sensing elements arrayed across the detector surface. Each sensing elements may comprise a plurality of switching elements for selectively coupling and decoupling the sensing elements to and from each other, as well as to and from other circuitry and wiring paths in the detector. The plurality of switching elements may comprise a switch matrix of the detector.

At step S1301 a charged particle beam process begins. The charged particle beam process may be, e.g., a SEM inspection process. In particular, the process may be a beam mode operation in which a primary electron beam irradiates a sample surface to generate a corresponding secondary beam which produces a beam spot on a region of the detector surface. The region may comprise a plurality of sensing elements. In some embodiments there may be an array of primary electron beams irradiating the sample surface to generate a corresponding array of secondary beams which produce an array of beam spots on distinct regions of the detector surface. A group of sensing elements may be selected to correspond to the beam spot based on, e.g. a prior picture mode imaging operation. For example, a continuous group of sensing elements may be chosen that corresponds to the shape, size and location of a beam spot on the detector as determined by a high-resolution picture mode image of the beam spot. The beam spot may overlap the group of sensing elements, but may not be coextensive with it. Sensing elements within the chosen group may be operatively coupled to each other by closing a plurality of switching elements in the switch matrix. In this way, signals generated at each sensing element in the group, by irradiation of a beam spot onto the group, may be directed to a common signal readout path of the detector to produce a common measurement (e.g., an intensity measurement) of the beam spot.

At step S1302, a sensing element is identified as a candidate for updating the group by dynamic switching during the charged particle beam process. A candidate may be selected for its potential to be either added to, or removed from, the group. For example, an ungrouped sensing element may be added to the group if the beam spot is irradiating the ungrouped sensing element. A grouped sensing element may be removed from the group if it is not being irradiated by the beam spot. These two scenarios are more likely to occur at sensing elements proximal to a boundary of the group. Therefore, a sensing element may be considered a candidate if, e.g., it is proximal to the boundary of the group selected for the beam spot. For example, a sensing element may be a candidate if it is adjacent to the boundary of the group. Adjacent sensing elements on an outside of the boundary may be candidates for adding to the group, while adjacent sensing elements on an inside of the boundary may be candidates for removing from the group. Stated another way, a sensing element may be a candidate for updating when a neighboring element has a different grouping status. For example, a sensing element may be a candidate for adding to a group if one of its neighboring sensing elements is already a member of the group. A sensing element may be a candidate for removing from a group if one of its neighboring sensing elements is not a member of the group.

A detector control circuit may continually identify a plurality of candidate sensing elements substantially simultaneously, and once a thresholding operation is initiated as described below, each of the candidate sensing elements may proceed through the remaining steps in parallel in a semi-autonomous fashion. This may continue until, e.g., the charged particle beam process is complete. Alternatively, the candidate sensing elements may be identified at predetermined repeating intervals. The candidate sensing elements may also be identified at irregular intervals, such as when it is determined that a beam spot boundary may require updating based on other performance parameters.

At step S1303, a threshold circuit within the candidate sensing element performs a thresholding operation. This thresholding operation may be initiated by a control circuit (such as controller 904 of FIG. 9, controller 109 of FIG. 1 or image processing system 290 of FIG. 2) based on a determination that the sensing element is a candidate. At least a portion of the current (if any) generated at a diode of the sensing element may be diverted to the threshold circuit of the sensing element as a signal and measured or compared to a threshold. For example, a comparator of the threshold circuit may compare the signal to a chosen threshold. The threshold may vary depending on whether the sensing element is a candidate for adding or removing. For instance, if the sensing element is a candidate for adding to the group, the threshold circuit may compare the signal to a first threshold. If the sensing element is a candidate for removing from the group, the threshold circuit may compare the signal to a second threshold. The second threshold may be equal to, or lower than, the first threshold.

At step S1304 if the threshold comparison is not satisfied, the thresholding circuit does not cause any switching elements within the candidate sensing element to actuate. The method proceeds to step S1305. If the sensing element is still a candidate, the thresholding operation continues at step S1306. This loop may continue until either the threshold is satisfied or the sensing element is no longer a candidate. If the sensing element ceases to be a candidate (such as, e.g., due to the boundary shift illustrated at FIG. 12D, or due to the charged particle beam process ending), the thresholding operation terminates at step S1307. Therefore, in some embodiments of the present disclosure, a thresholding operation may remain active once initiated until the sensing element is no longer a candidate or the threshold is satisfied.

At step S1304 if the threshold is satisfied, then the method proceeds to step S1308. For instance, a candidate for adding may proceed to step S1308 if a signal from the diode to the threshold circuit exceeds a first threshold. A candidate for removing may proceed to step S1308 if a signal from the diode to the threshold circuit is below a second threshold.

At step S1308, a switching element is actuated in order add (or remove) the sensing element to (or from) the group. For instance, a candidate for adding may be added to the group. In such a case, for instance, a switching element may be closed to pass charge from the added sensing element to the group. The switching element may be, e.g., an inter-element switching element between the added sensing element and an adjacent element that belongs to the group already. The particular switch to be actuated may be selected by a control signal provided, e.g. during initiation of the thresholding operation. The added sensing element is then part of the group, and a new boundary exists around the group of sensing elements. In some embodiments, an added sensing element may immediately become a candidate for removing because it has become the outermost sensing element in the group. In some embodiments, a time delay or other buffer signal may be applied to prevent immediate candidacy so as to prevent the sensing element from repeatedly flickering off and on by the thresholding operation. In some embodiments, such flicker may be avoided by setting a sufficient difference between the first and second thresholds. In some embodiments, such flicker may simply be tolerated or not considered problematic.

If instead at step S1308 the sensing element is a candidate for removing that is removed from the group, the threshold circuit may actuate a selected switching element to prevent any further charge from passing from the removed sensing element to the group. The removed sensing element may be disconnected entirely from the group to minimize the influence of parasitic parameters on the group from the removed sensing element. The removed sensing element is then no longer part of the group, and a new boundary exists around the remaining group of sensing elements. In some embodiments, a removed sensing element may immediately become a candidate for adding because it has become an ungrouped sensing element adjacent to the new boundary. The same flicker considerations discussed above with respect to the adding scenario may apply equally to the removing scenario.

After step S1308, the process ends with respect to the particular sensing element. However, as discussed above, in some embodiments of the present disclosure this process may be continually occurring at all candidate sensing elements so that a sensing element group may be continuously updated during a charged particle beam process.

A non-transitory computer-readable medium may be provided that stores instructions for a processor of a controller (e.g., controller 109 in FIG. 1 or controller 904 in FIG. 9) for detecting a charged-particle beam according to the exemplary flowcharts of FIG. 13 above, consistent with embodiments in the present disclosure. For example, the instructions stored in the non-transitory computer-readable medium may be executed by the circuitry of the controller for performing method 1300 part or in entirety. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

Embodiments of the present disclosure may further be described by the following clauses:
1. A charged particle detector comprising:
   a substrate;
   a plurality of switching elements formed on the substrate and configured to form a switching matrix, the switching matrix having a plurality of inputs, each of the inputs being configured to connect to a different one of a plurality of sensing elements, each of the sensing elements being configured to generate a signal in response to a charged particle impacting the sensing element, the switching matrix being configured to combine a grouping of signals generated from a grouping of sensing elements, the grouping of sensing elements being associated with a charged particle beam spot formed on the charged particle detector; and
   a plurality of threshold circuits, each of the threshold circuits being coupled to a different one of the plurality of sensing elements,
   wherein a first threshold circuit of the plurality of threshold circuits is coupled to a first sensing element of the plurality of sensing elements and is configured to actuate a first switching element of the switch matrix based on a comparison of a signal level of the first sensing element to a threshold;
   wherein the first sensing element is configured to be identified as a candidate for one of being added to the grouping of sensing elements and being removed from the grouping of sensing elements based on proximity of the first sensing element to a boundary of the grouping of sensing elements; and
   wherein the first threshold circuit is configured to initiate the comparison in response to the first sensing element being identified as the candidate.
2. The charged particle detector of clause 1, wherein the first threshold circuit is configured to close the first switching element, to cause the first switching element to conduct current, in response to the signal level of the first sensing element exceeding the threshold.
3. The charged particle detector of clause 2, wherein the first sensing element is added to the grouping of sensing elements by the closing of the first switching element by the first threshold circuit to cause the signal from the first sensing element to be combined with the grouping of signals generated from the grouping of sensing elements.
4. The charged particle detector of clause 3,
   wherein the threshold is a first threshold, and
   the first threshold circuit is configured to open the first switching element, to prevent the first switching element from conducting current, in response to the signal level of the first sensing element falling below a second threshold, wherein the second threshold is lower than the first threshold.
5. The charged particle detector of clause 4, wherein the first sensing element is removed from the grouping of sensing elements by the opening of the first switching element by the first threshold circuit to prevent the signal from the first sensing element from being combined with the grouping of signals generated from the grouping of sensing elements.
6. The charged particle detector of clause 1, wherein the first threshold circuit is configured to open the first switching element, to prevent the first switching element from conducting current, in response to the signal level of the first sensing element falling below the threshold.
7. The charged particle detector of clause 6, wherein the first sensing element is removed from the grouping of sensing elements by the opening of the first switching element by the first threshold circuit to prevent the signal from the first sensing element from being combined with the grouping of signals generated from the grouping of sensing elements.
8. The charged particle detector of clause 7,
   wherein the threshold is a second threshold, and
   the first threshold circuit is configured to close the first switching element, to cause the first switching element to conduct current, in response to the signal level of the first sensing element exceeding a first threshold, wherein the first threshold is higher than the second threshold.
9. The charged particle detector of clause 8, wherein the first sensing element is added to the grouping of sensing elements by the closing of the first switching element by the first threshold circuit to cause the signal from the first sensing element to be combined with the grouping of signals generated from the grouping of sensing elements.
10. The charged particle detector of clause 1, wherein the sensing element comprises a diode.
11. The charged particle detector of clause 1, wherein the threshold comprises a threshold charge or current.
12. The charged particle detector of clause 1, further comprising:
   a second sensing element adjacent to the first sensing element;
   wherein proximity of the first sensing element to a boundary of the grouping of sensing elements is determined based on the first sensing element having a different grouping status from the second sensing element.
13. The charged particle detector of clause 12, wherein:
   the first sensing element is in a grouped status with the grouping of sensing elements;
   the second sensing element is in an ungrouped status from the grouping of sensing elements;
   the first sensing element is a candidate for being removed from the grouping of sensing elements; and
   the second sensing element is a candidate for being added to the grouping of sensing elements.
14. The charged particle detector of clause 13, wherein the first threshold circuit is configured to remove the first sensing element from the grouping of sensing elements by opening the first switching element in response to the fist signal level being below the threshold.
15. The charged particle detector of clause 14, wherein:
   in response to being removed from the grouping of sensing elements by the first threshold circuit, the first sensing element is configured to be identified as a candidate for adding to the grouping of sensing elements; and
   the first threshold circuit is configured to initiate a second a comparison of a signal level of the first sensing element to a second threshold in response to the first sensing element being identified as the candidate for adding to the grouping of sensing elements.
16. The charged particle detector of clause 12, wherein:
   the first sensing element is in an ungrouped status from the grouping of sensing elements;
   the second sensing element is in a grouped status with the grouping of sensing elements;
   the first sensing element is a candidate for being added to the grouping of sensing elements; and
   the second sensing element is a candidate for being removed from the grouping of sensing elements
17. The charged particle detector of clause 16, wherein the first threshold circuit is configured to add the first sensing element to the grouping of sensing elements by closing the first switching element in response to the first signal level exceeding the threshold.
18. The charged particle detector of clause 17, wherein the second sensing element is coupled to the first sensing element by the first switching element.
19. The charged particle detector of clause 17, wherein:
   in response to being added to the grouping of sensing elements by the first threshold circuit, the first sensing element is configured to be identified as a candidate for removing from the grouping of sensing elements; and
   the first threshold circuit is configured to initiate a second a comparison of a signal level of the first sensing element to a second threshold in response to the first sensing element being identified as the candidate for removing from the grouping of sensing elements.
20. The charged particle detector of clause 1, wherein the substrate includes the plurality of transistors.
21. A method of updating a grouping of sensing elements in a charged particle detector, the method comprising:
   irradiating a sample to produce a secondary beam spot on the charged particle detector, the secondary beam spot overlapping the grouping of sensing elements;
   identifying a first sensing element as a candidate for updating a grouping status of the first sensing element based on proximity of the first sensing element to a boundary of the grouping of sensing elements;
   initiating a thresholding operation of the first sensing element by a first threshold circuit, the first threshold circuit being coupled to the first sensing element and to a first switching element of a switching matrix of the charged particle detector;
   wherein the thresholding operation comprises comparing a signal level of the first sensing element to a threshold; and
   actuating the first switching element to update the grouping status of the sensing element based on the comparison.
22. The method of clause 21, wherein identifying the first sensing element as a candidate for updating the grouping status of the first sensing element based on proximity of the first sensing element to a boundary of the grouping of sensing elements comprises determining if a neighboring sensing element adjacent to the first sensing element has a different grouping status from the first sensing element.
23. The method of clause 22, wherein the first sensing element is a grouped sensing element, and the neighboring sensing element is an ungrouped sensing element.
24. The method of clause 22, wherein the first sensing element is an ungrouped sensing element, and the neighboring sensing element is a grouped sensing element.
25. The method of clause 21, wherein:
   the comparison comprises determining that the signal level of the first sensing element exceeds the threshold;
   actuating the first switching element comprises closing the first switching element to cause the first switching element to conduct current; and
   updating the grouping status of the first sensing element comprises adding the first sensing element to the grouping of sensing elements.
26. The method of clause 25,
   wherein the threshold is a first threshold,
   the method further comprising determining that the signal level of the first sensing element falls below a second threshold;
   opening the first switching element, to prevent the first switching element from conducting current; and updating the grouping status of the first sensing element to remove the first sensing element from the grouping of sensing elements.
27. The method of clause 25, further comprising:
   identifying a second sensing element as a candidate for updating a grouping status of the second sensing element after the first sensing element is added to the grouping of sensing elements;
   wherein the second sensing element is adjacent to the first sensing element.
28. The method of clause 27, further comprising
   initiating a further thresholding operation of the second sensing element by a second threshold circuit, the second threshold circuit being coupled to the second sensing element and to a second switching element of the switching matrix of the detector;
   wherein the further thresholding operation comprises comparing a signal level of the second sensing element to a further threshold; and
   actuating the second switching element to update the grouping status of the sensing element based on the comparison with the further threshold.
29. The method of clause 21, wherein:
   the comparison comprises determining that the signal level of the first sensing element falls below the threshold;
   actuating the first switching element comprises opening the first switching element, to prevent the first switching element from conducting current; and
   updating the grouping status of the first sensing element comprises removing the first sensing element from the grouping of sensing elements.
30. The method of clause 29,
   wherein the threshold is a second threshold,
   the method further comprising determining that the signal level of the first sensing element exceeds a first threshold;
   closing the first switching element to cause the first switching element to conduct current; and
   updating the grouping status of the first sensing element to add the first sensing element to the grouping of sensing elements.
31. The method of clause 29, further comprising:
   terminating a candidate status of a second sensing element after the first sensing element is removed from the grouping of sensing elements, the second sensing element being adjacent to the first sensing element and not adjacent to a boundary of the grouping of sensing elements.
32. The method of clause 21, wherein the thresholding operation continues until the threshold is met or the threshold operation is terminated by a controller of the charged particle detector.
33. The method of clause 21, wherein proximity of the first sensing element to the boundary of the grouping of sensing elements comprises the first sensing element being adjacent to the boundary of the grouping of sensing elements.
34. The method of clause 21, wherein the first sensing element is identified as a candidate for updating the grouping status of the first sensing element in response to the first sensing element being adjacent to a boundary of the grouping of sensing elements.
35. A non-transitory computer-readable medium that stores a set of instructions that is executable by at least one processor of an apparatus to cause the apparatus to perform a method of updating a grouping of sensing elements based on a beam spot being exposed on a charged particle detector, the method comprising:
   identifying a first sensing element as a candidate for updating a grouping status of the first sensing element based on proximity of the first sensing element to a boundary of the grouping of sensing elements;
   initiating a thresholding operation of the first sensing element by a first threshold circuit, the first threshold circuit being coupled to the first sensing element and to a first switching element of a switching matrix of the detector;
   wherein the thresholding operation comprises comparing a signal level of the first sensing element to a threshold; and
   actuating the first switching element to update the grouping status of the sensing element based on the comparison.
36. The non-transitory computer-readable medium of clause 35, wherein identifying the first sensing element as a candidate for updating the grouping status of the first sensing element based on proximity of the first sensing element to a boundary of the grouping of sensing elements comprises determining if a neighboring sensing element adjacent to the first sensing element has a different grouping status from the first sensing element.
37. The non-transitory computer-readable medium of clause 36, wherein the first sensing element is a grouped sensing element, and the neighboring sensing element is an ungrouped sensing element.
38. The non-transitory computer-readable medium of clause 36, wherein the first sensing element is an ungrouped sensing element, and the neighboring sensing element is a grouped sensing element.
39. The non-transitory computer-readable medium of clause 35, wherein:
   the comparison comprises determining that the signal level of the first sensing element exceeds the threshold;
   actuating the first switching element comprises closing the first switching element to cause the first switching element to conduct current; and
   updating the grouping status of the first sensing element comprises adding the first sensing element to the grouping of sensing elements.
40. The non-transitory computer-readable medium of clause 39,
   wherein the threshold is a first threshold,
   the set of instructions that is executable by at least one processor of an apparatus being configured to cause the apparatus to further perform:
   determining that the signal level of the first sensing element falls below a second threshold; opening the first switching element, to prevent the first switching element from conducting current; and
   updating the grouping status of the first sensing element to remove the first sensing element from the grouping of sensing elements.
41. The non-transitory computer-readable medium of clause 39, wherein the set of instructions that is executable by at least one processor of an apparatus causes the apparatus to further perform:
   identifying a second sensing element as a candidate for updating a grouping status of the second sensing element after the first sensing element is added to the grouping of sensing elements;
   wherein the second sensing element is adjacent to the first sensing element.
42. The non-transitory computer-readable medium of clause 41, wherein the set of instructions that is executable by at least one processor of an apparatus causes the apparatus to further perform:
   initiating a further thresholding operation of the second sensing element by a second threshold circuit, the second threshold circuit being coupled to the second sensing element and to a second switching element of the switching matrix of the detector;
   wherein the further thresholding operation comprises comparing a signal level of the second sensing element to a further threshold; and
   actuating the second switching element to update the grouping status of the sensing element based on the comparison with the further threshold.
43. The non-transitory computer-readable medium of clause 35, wherein:
   the comparison comprises determining that the signal level of the first sensing element falls below the threshold;
   actuating the first switching element comprises opening the first switching element, to prevent the first switching element from conducting current; and
   updating the grouping status of the first sensing element comprises removing the first sensing element from the grouping of sensing elements.
44. The non-transitory computer-readable medium of clause 43,
   wherein the threshold is a second threshold,
   the set of instructions that is executable by at least one processor of an apparatus being configured to cause the apparatus to further perform:
   determining that the signal level of the first sensing element exceeds a first threshold; closing the first switching element to cause the first switching element to conduct current; and
   updating the grouping status of the first sensing element to add the first sensing element to the grouping of sensing elements.
45. The non-transitory computer-readable medium of clause 43, wherein the set of instructions that is executable by at least one processor of an apparatus causes the apparatus to further perform:
   terminating a candidate status of a second sensing element after the first sensing element is removed from the grouping of sensing elements, the second sensing element being adjacent to the first sensing element and not adjacent to the boundary of the grouping of sensing elements.
46. The non-transitory computer-readable medium of clause 35, wherein proximity of the first sensing element to the boundary of the grouping of sensing elements comprises the first sensing element being adjacent to the boundary of the grouping of sensing elements.
47. The non-transitory computer-readable medium of clause 35, wherein the thresholding operation continues until one of the threshold is met or the threshold operation is terminated by a controller of the detector.
48. The non-transitory computer-readable medium of clause 35, wherein the first sensing element comprises a PIN diode.
49. A non-transitory computer-readable medium that stores a set of instructions that is executable by at least one processor of an apparatus to cause the apparatus to perform a method, the method comprising:
   operatively coupling a grouping of sensing elements in a charged particle detector;
   updating the grouping of sensing elements by one of:
   adding a candidate sensing element to the grouping by operatively coupling the candidate sensing element to the grouping, or
   removing the candidate sensing element from the grouping by operatively decoupling the candidate sensing element from the grouping;
   wherein the updating takes place during a charged particle exposure operation on the charged particle detector.
50. A method, comprising:
   operatively coupling a grouping of sensing elements in a charged particle detector; updating the grouping of sensing elements by one of:
   adding a candidate sensing element to the grouping by operatively coupling the candidate sensing element to the grouping, or
   removing the candidate sensing element from the grouping by operatively decoupling the candidate sensing element from the grouping;
   wherein the updating takes place during a charged particle exposure operation on the charged particle detector.
51. A system comprising:
   a charged particle detector comprising a plurality of sensing elements;
   a controller having circuitry configured to:
   operatively couple a grouping of sensing elements of the plurality of sensing elements;
   update the grouping of sensing elements during charged particle exposure on the charged particle detector by one of:
   add a candidate sensing element to the grouping by operatively coupling the candidate sensing element to the grouping, or
   remove a candidate sensing element from the grouping by operatively decoupling the candidate sensing element from the grouping.
52. A non-transitory computer-readable medium that stores a set of instructions that is executable by at least one processor of an apparatus to cause the apparatus to perform a method, the method comprising:
   operatively coupling a grouping of sensing elements in a charged particle detector;
   identifying a first sensing element as a candidate for updating the grouping of sensing elements by one of:
   adding the first sensing element to the grouping by operatively coupling the candidate sensing element to the grouping, or
   removing the first sensing element from the grouping by operatively decoupling the candidate sensing element from the grouping;
   wherein identifying the first sensing element as a candidate is based on proximity of the first sensing element to a second sensing element that is part of the grouping of sensing elements.
53. A method, comprising:
   operatively coupling a grouping of sensing elements in a charged particle detector;
   identifying a first sensing element as a candidate for updating the grouping of sensing elements by one of:
   adding the first sensing element to the grouping by operatively coupling the candidate sensing element to the grouping, or
   removing the first sensing element from the grouping by operatively decoupling the candidate sensing element from the grouping;
   wherein identifying the first sensing element as a candidate is based on proximity of the first sensing element to a second sensing element that is part of the grouping of sensing elements.
54. A system comprising:
   a charged particle detector comprising a plurality of sensing elements;
   a controller having circuitry configured to:
   operatively couple a grouping of sensing elements of the plurality of sensing elements;
   identify a first sensing element as a candidate for updating the grouping of sensing elements by one of:
   add the first sensing element to the grouping by operatively coupling the candidate sensing element to the grouping, or
   remove the first sensing element from the grouping by operatively decoupling the candidate sensing element from the grouping;
   wherein identifying the first sensing element as a candidate is based on proximity of the first sensing element to a second sensing element that is part of the grouping of sensing elements.
55. A method of reducing noise of an electron detector of a multi-beam SEM comprising:
   receiving, by sensing elements of an electron detector, electrons from multiple secondary electron beams emitted by a sample in response to a plurality of primary beams of the multi-beam SEM interacting with the sample, each of the secondary beams being associated with a different one of the plurality of primary beams;
   based on the received electrons, coupling a first grouping of the sensing elements of the electron detector corresponding to a first beam spot of one of the secondary electron beams; and
   adjusting the first grouping of sensing elements comprising:
   coupling a first sensing element to the first grouping in response to a first detected charge at the first sensing element exceeding a first threshold, wherein coupling the first sensing element to the first grouping enables charge to be passed from the first sensing element to a signal readout path of the first grouping; or
   decoupling a second sensing element from the first grouping in response to a second detected charge at the second sensing element falling below a second threshold, wherein decoupling the second sensing element from the first grouping prevents charge from being passed from the second sensing element to the signal readout path of the first grouping.
56. The method of clause 55, wherein the first and second thresholds are equal.
57. The method of clause 55, wherein the first threshold is greater than the second threshold.
58. The method of clause 57, wherein:
   the first detected charge exceeds the first threshold and is passed to the signal readout path,
   the first detected charge subsequently falls to an intermediate range below the first threshold and above the second threshold,
   the method further comprising:
   in response to the first detected charge falling into the intermediate range, continuing to enable the detected charge to be passed to the signal readout path.
59. The method of clause 57, wherein:
   the second detected charge does not exceed the second threshold and is prevented from being passed to the signal readout path,
   the second detected charge subsequently rises to an intermediate range below the first threshold and above the second threshold,
   the method further comprising:
   in response to the second detected charge rising to the intermediate range, continuing to prevent the detected charge from being passed to the signal readout path.
60. The method of clause 55, wherein:
   the first sensing element exists within a first section of sensing elements;
   each sensing element in the first section is coupled to an element bus switching element;
   each element bus switching element in the first section is configured to couple its respective sensing element to a common node of the first section.
61. The method of clause 60, wherein the first detected charge exceeds the first threshold and is passed to the signal readout path by closing an element bus switching element.
62. The method of clause 61, wherein:
   the first section of sensing elements is adjacent to a second section of sensing elements;
   the second section of sensing elements comprises a third sensing element belonging to the first grouping; and
   the first section of sensing elements and the second section of sensing elements are configured to be coupled to each other by an interconnection switching element;
   wherein the first detected charge is further passed to the signal readout path by closing the interconnection switching element.
63. The method of clause 55, wherein
   the first sensing element is adjacent to a third sensing element, the third sensing element belonging to the first grouping; and
   the first sensing element is configured to be coupled to the third sensing element by an inter-element switching element.
64. The method of clause 63, wherein the first detected charge exceeds the first threshold and is passed to the signal readout path by closing the inter-element switching element.
65. The method of clause 55, wherein:
   the second sensing element exists within a first section of sensing elements;
   each sensing element in the first section is coupled to an element bus switching element; and
   each element bus switching element in the first section is configured to couple its respective sensing element to a common node of the first section.
66. The method of clause 65, wherein the second detected charge is below the second threshold and is prevented from being passed to the signal readout path by opening an element bus switching element in the first section.
67. The method of clause 55, wherein
   the second sensing element is adjacent to a third sensing element, the third sensing element belonging to the first grouping; and
   the first sensing element is configured to be coupled to the third sensing element by an inter-element switching element.
68. The method of clause 67, wherein the second detected charge is below the second threshold and is prevented from passing to the signal readout path by opening the inter-element switching element.
69. The method of clause 55, wherein the sensing elements comprise PIN diodes.
70. The method of clause 55, wherein
   coupling the first element to the first grouping is performed by a first threshold circuit; and
   decoupling the second element from the first grouping is performed by a second threshold circuit.
71. The method of clause 55, wherein coupling the first element to the first grouping and decoupling the second element from the first grouping are performed by a single threshold circuit.
72. A non-transitory computer-readable medium that stores a set of instructions that is executable by at least one processor of an apparatus to cause the apparatus to perform a method, the method comprising:
   receiving, by sensing elements of an electron detector, electrons from multiple secondary electron beams emitted by a sample in response to a plurality of primary beams of the multi-beam SEM interacting with the sample, each of the secondary beams being associated with a different one of the plurality of primary beams;
   based on the received electrons, coupling a first grouping of the sensing elements of the electron detector corresponding to a first beam spot of one of the secondary electron beams; and
   coupling a first sensing element to the first grouping in response to a first detected charge at the first sensing element exceeding a first threshold, wherein coupling the first sensing element to the first grouping enables charge to be passed from the first sensing element to a signal readout path of the first grouping; or
   decoupling a second sensing element from the first grouping in response to a second detected charge at the second sensing element falling below a second threshold, wherein decoupling the second sensing element from the first grouping prevents charge from being passed from the second sensing element to the signal readout path of the first grouping.
73. The non-transitory computer-readable medium of clause 72, wherein the first and second thresholds are equal.
74. The non-transitory computer-readable medium of clause 72, wherein the first threshold is greater than the second threshold.
75. The non-transitory computer-readable medium of clause 74, wherein the set of instructions that is executable by at least one processor of an apparatus being configured to cause the apparatus to further perform:
   continuing to enable the detected charge to be passed to the signal readout path in response to:
   the first detected charge exceeding the first threshold and being passed to the signal readout path; and
   the first detected charge subsequently falling to an intermediate range below the first threshold and above the second threshold.
76. The non-transitory computer-readable medium of clause 74, wherein the set of instructions that is executable by at least one processor of an apparatus being configured to cause the apparatus to further perform:
   continuing to prevent the detected charge from being passed to the switch network in response to:
   the second detected charge not exceeding the second threshold and being prevented from being passed to the signal readout path; and
   the second detected charge subsequently rising to an intermediate range below the first threshold and above the second threshold.
77. The non-transitory computer-readable medium of clause 72, wherein:
   the first sensing element exists within a first section of sensing elements;
   each sensing element in the first section is coupled to an element bus switching element; and
   each element bus switching element in the first section is configured to couple its respective sensing element to a common node of the first section.
78. The non-transitory computer-readable medium of clause 77, wherein the set of instructions that is executable by at least one processor of an apparatus being configured to cause the apparatus to further perform:
   in response to the first detected charge exceeding the first threshold, passing the first detected charge to the signal readout path by closing an element bus switching element.
79. The non-transitory computer-readable medium of clause 78, wherein:
   the first section of sensing elements is adjacent a second section of sensing elements;
   the second section of sensing elements comprises a third sensing element belonging to the first grouping; and
   the first section of sensing elements and the second section of sensing elements are configured to be coupled to each other by an interconnection switching element;
   wherein the set of instructions that is executable by at least one processor of an apparatus is configured to cause the apparatus to further perform:
   further passing the first detected charge to the signal readout path by closing the interconnection switching element.
80. The non-transitory computer-readable medium of clause 72, wherein
   the first sensing element is adjacent to a third sensing element, the third sensing element belonging to the first grouping; and
   the first sensing element is configured to be coupled to the third sensing element by an inter-element switching element.
81. The non-transitory computer-readable medium of clause 80, wherein the set of instructions that is executable by at least one processor of an apparatus being configured to cause the apparatus to further perform:
   passing the first detected charge to the signal readout path by closing the inter-element switching element in response to the first detected charge exceeding the first threshold.
82. The non-transitory computer-readable medium of clause 72, wherein:
   the second sensing element exists within a first section of sensing elements;
   each sensing element in the first section is coupled to an element bus switching element; and
   each element bus switching element in the first section is configured to couple its respective sensing element to a common node of the first section.
83. The non-transitory computer-readable medium of clause 82, wherein the set of instructions that is executable by at least one processor of an apparatus being configured to cause the apparatus to further perform:
   preventing the second detected charge from being passed to the signal readout path by opening an element bus switching element in the first section in response to the second detected charge being below the second threshold.
84. The non-transitory computer-readable medium of clause 72, wherein
   the second sensing element is adjacent to a third sensing element, the third sensing element belonging to the first grouping; and
   the first sensing element is configured to be coupled to the third sensing element by an inter-element switching element.
85. The non-transitory computer-readable medium of clause 84, wherein the set of instructions that is executable by at least one processor of an apparatus being configured to cause the apparatus to further perform:
   preventing the second detected charge from being passed to the signal readout path by opening the inter-element switching element in response to the second detected charge being below the second threshold.
86. The non-transitory computer-readable medium of clause 72, wherein the sensing elements comprise PIN diodes.
87. The non-transitory computer-readable medium of clause 72, wherein the set of instructions that is executable by at least one processor of an apparatus being configured to cause the apparatus to further perform:
   coupling the first element to the first grouping by a first threshold circuit; and
   decoupling the second element from the first grouping by a second threshold circuit.
88. The non-transitory computer-readable medium of clause 72, wherein the set of instructions that is executable by at least one processor of an apparatus being configured to cause the apparatus to further perform:
   coupling the first element to the first grouping and decoupling the second element from the first grouping by a single threshold circuit.
89. A system comprising:
   a charged particle detector comprising a plurality of sensing elements that receives electrons from multiple secondary electron beams emitted by a sample in response to a plurality of primary beams of the multi-beam SEM interacting with the sample, each of the secondary beams being associated with a different one of the plurality of primary beams; and
   a controller having circuitry configured to perform:
   based on the received electrons, coupling a first grouping of the sensing elements of the electron detector corresponding to a first beam spot of one of the secondary electron beams; and
   coupling a first sensing element to the first grouping in response to a first detected charge at the first sensing element exceeding a first threshold, wherein coupling the first sensing element to the first grouping enables charge to be passed from the first sensing element to a signal readout path of the first grouping; or
   decoupling the second sensing element from the first grouping in response to a second detected charge at the second sensing element falling below a second threshold, wherein decoupling the second element from the first grouping prevents charge from being passed from the second sensing element to the signal readout path of the first grouping.
90. The system of clause 89, wherein the first and second thresholds are equal.
91. The system of clause 89, wherein the first threshold is greater than the second threshold.
92. The system of clause 91, wherein the controller having circuitry configured to further perform: continuing to enable the detected charge to be passed to the signal readout path in response to:
   the first detected charge exceeding the first threshold and being passed to the signal readout path; and
   the first detected charge subsequently falling to an intermediate range below the first threshold and above the second threshold.
93. The system of clause 91, wherein the controller having circuitry configured to further perform:
   continuing to prevent the detected charge from being passed to the switch network in response to:
   the second detected charge not exceeding the second threshold and being prevented from being passed to the signal readout path; and
   the second detected charge subsequently rising to an intermediate range below the first threshold and above the second threshold.
94. The system of clause 89, wherein:
   the first sensing element exists within a first section of sensing elements;
   each sensing element in the first section is coupled to an element bus switching element; and
   each element bus switching element in the first section is configured to couple its respective sensing element to a common node of the first section.
95. The system of clause 94, wherein the controller having circuitry configured to further perform:
   in response to the first detected charge exceeding the first threshold, passing the first detected charge to the signal readout path by closing an element bus switching element.
96. The system of clause 95, wherein:
   the first section of sensing elements is adjacent a second section of sensing elements;
   the second section of sensing elements comprises a third sensing element belonging to the first grouping; and
   the first section of sensing elements and the second section of sensing elements are configured to be coupled to each other by an interconnection switching element;
   wherein the controller has circuitry configured to further perform:
   further passing the first detected charge to the signal readout path by closing the interconnection switching element.
97. The system of clause 89, wherein
   the first sensing element is adjacent to a third sensing element, the third sensing element belonging to the first grouping; and
   the first sensing element is configured to be coupled to the third sensing element by an inter-element switching element.
98. The system of clause 97, wherein the controller having circuitry configured to further perform:
   passing the first detected charge to the signal readout path by closing the inter-element switching element in response to the first detected charge exceeding the first threshold.
99. The system of clause 89, wherein:
   the second sensing element exists within a first section of sensing elements;
   each sensing element in the first section is coupled to an element bus switching element; and
   each element bus switching element in the first section is configured to couple its respective sensing element to a common node of the first section.
100. The system of clause 99, wherein the controller having circuitry configured to further perform:
   preventing the second detected charge from being passed to the signal readout path by opening an element bus switching element in the first section in response to the second detected charge being below the second threshold.
101. The system of clause 89, wherein
   the second sensing element is adjacent to a third sensing element, the third sensing element belonging to the first grouping; and
   the first sensing element is configured to be coupled to the third sensing element by an inter-element switching element.
102. The system of clause 101, wherein the controller having circuitry configured to further perform:
   preventing the second detected charge from being passed to the signal readout path by opening the inter-element switching element in response to the second detected charge being below the second threshold.
103. The system of clause 89, wherein the sensing elements comprise PIN diodes.
104. The system of clause 89, wherein the controller having circuitry configured to further perform:
   coupling the first sensing element to the first group by a first threshold circuit; and
   decoupling the second sensing element from the first group by a second threshold circuit.
105. The system of clause 89, wherein the controller having circuitry configured to further perform:
   coupling the first sensing element to the first group and decoupling the second sensing element from the first group by a single threshold circuit.
106. A method of updating a grouping of sensing elements in a charged particle detector, the method comprising:
   irradiating a sample to produce a secondary beam spot on the charged particle detector, the secondary beam spot overlapping the grouping of sensing elements;
   identifying a first sensing element as a candidate for updating a grouping status of the first sensing element; and
   initiating a thresholding operation of the first sensing element by a first threshold circuit, the first threshold circuit being coupled to the first sensing element and to a first switching element of a switching matrix of the charged particle detector;
   wherein the thresholding operation comprises comparing a signal level of the first sensing element to a threshold.
107. The method of clause 106, further comprising:
   actuating the first switching element to update the grouping status of the sensing element based on the comparison.
108. The method of clause 106, wherein the first switching element is in an open status to allow the switching element to conduct current prior to initiating the thresholding operation, the method further comprising:
   leaving the grouping status of the sensing element unchanged by maintain the first switching element in the open status.
109. The method of clause 106, wherein the first switching element is in a closed status to prevent the switching element from conducting current prior to initiating the thresholding operation, the method further comprising:
   leaving the grouping status of the sensing element unchanged by maintain the first switching element in the closed status.
110. A detector comprising:
   a substrate;
   a plurality of switching elements formed on the substrate and configured to form a switching matrix,
   the switching matrix having a plurality of inputs, each of the inputs being configured to connect to a different one of a plurality of sensing elements, each of the sensing elements being configured to generate a signal in response to an arrival of energy at the sensing element, the switching matrix being configured to combine a grouping of signals generated from a grouping of sensing elements, the grouping of sensing elements being associated with a beam spot formed on the detector; and
   a plurality of transistors forming a plurality of threshold circuits, each of the threshold circuits being coupled to a different one of the plurality of sensing elements,
   wherein a first threshold circuit of the plurality of threshold circuits is coupled to a first sensing element of the plurality of sensing elements and is configured to actuate a first switching element of the switch matrix based on a comparison of a signal level of the first sensing element to a threshold.
111. The apparatus of clause 110, wherein the detector is configured to detect electrons, and the arrival of energy at the sensing element comprises an electron landing event.
112. The apparatus of clause 110, wherein the detector is configured to detect protons, and the arrival of energy at the sensing element comprises a proton landing event.
113. The apparatus of clause 110, wherein the detector is configured to detect photons, and the arrival of energy at the sensing element comprises a photon landing event.
114. A method of updating a grouping of sensing elements in a detector, the method comprising:
   irradiating a sample to produce a secondary beam spot on the detector, the secondary beam spot overlapping the grouping of sensing elements;
   identifying a first sensing element as a candidate for updating a grouping status of the first sensing element, the sensing element being configured to generate a signal in response to an arrival of energy at the sensing element;
   initiating a thresholding operation of the first sensing element by a first threshold circuit, the first threshold circuit being coupled to the first sensing element and to a first switching element of a switching matrix of the detector;
   wherein the thresholding operation comprises comparing a signal level of the first sensing element to a threshold; and
   actuating the first switching element to update the grouping status of the sensing element based on the comparison.
115. The method of clause 114, wherein the detector is configured to detect electrons, and the arrival of energy at the sensing element comprises an electron landing event.
116. The method of clause 114, wherein the detector is configured to detect protons, and the arrival of energy at the sensing element comprises a proton landing event.
117. The method of clause 114, wherein the detector is configured to detect photons, and the arrival of energy at the sensing element comprises a photon landing event.
118. A system comprising:
   a charged particle detector comprising a plurality of sensing elements and configured to be exposed to a beam spot that overlaps on a grouping of sensing elements;
   a controller having circuitry configured to update the grouping of sensing elements in a charged particle detector by:
   identifying a first sensing element as a candidate for updating a grouping status of the first sensing element based on proximity of the first sensing element to a boundary of the grouping of sensing elements;
   initiating a thresholding operation of the first sensing element by a first threshold circuit, the first threshold circuit being coupled to the first sensing element and to a first switching element of a switching matrix of the charged particle detector;
   wherein the thresholding operation comprises comparing a signal level of the first sensing element to a threshold; and
   actuating the first switching element to update the grouping status of the sensing element based on the comparison.
119. The system of clause 118, wherein identifying the first sensing element as a candidate for updating the grouping status of the first sensing element based on proximity of the first sensing element to a boundary of the grouping of sensing elements comprises determining if a neighboring sensing element adjacent to the first sensing element has a different grouping status from the first sensing element.
120. The system of clause 119, wherein the first sensing element is a grouped sensing element, and the neighboring sensing element is an ungrouped sensing element.
121. The system of clause 119, wherein the first sensing element is an ungrouped sensing element, and the neighboring sensing element is a grouped sensing element.
122. The system of clause 118, wherein:
   the comparison comprises determining that the signal level of the first sensing element exceeds the threshold;
   actuating the first switching element comprises closing the first switching element to cause the first switching element to conduct current; and
   updating the grouping status of the first sensing element comprises adding the first sensing element to the grouping of sensing elements.
123. The system of clause 122,
   wherein the threshold is a first threshold,
   wherein the controller has circuitry configured to further perform:
   determining that the signal level of the first sensing element falls below a second threshold;
   opening the first switching element, to prevent the first switching element from conducting current; and
   updating the grouping status of the first sensing element to remove the first sensing element from the grouping of sensing elements.
124. The system of clause 122, the controller having circuitry configured to further perform: identifying a second sensing element as a candidate for updating a grouping status of the second sensing element after the first sensing element is added to the grouping of sensing elements; wherein the second sensing element is adjacent to the first sensing element.
125. The system of clause 124, the controller having circuitry configured to further perform:
   initiating a further thresholding operation of the second sensing element by a second threshold circuit,
   the second threshold circuit being coupled to the second sensing element and to a second switching element of the switching matrix of the detector;
   wherein the further thresholding operation comprises comparing a signal level of the second sensing element to a further threshold; and
   actuating the second switching element to update the grouping status of the sensing element based on the comparison with the further threshold.
126. The system of clause 124, wherein:
   the comparison comprises determining that the signal level of the first sensing element falls below the threshold;
   actuating the first switching element comprises opening the first switching element, to prevent the first switching element from conducting current; and
   updating the grouping status of the first sensing element comprises removing the first sensing element from the grouping of sensing elements.
127. The system of clause 126,
   wherein the threshold is a second threshold,
   wherein the controller has circuitry configured to further perform:
   determining that the signal level of the first sensing element exceeds a first threshold;
   closing the first switching element to cause the first switching element to conduct current; and
   updating the grouping status of the first sensing element to add the first sensing element to the grouping of sensing elements.
128. The system of clause 126, the controller having circuitry configured to further perform:
   terminating a candidate status of a second sensing element after the first sensing element is removed from the grouping of sensing elements, the second sensing element being adjacent to the first sensing element and not adjacent to a boundary of the grouping of sensing elements.
129. The system of clause 118, wherein the thresholding operation continues until the threshold is met or the threshold operation is terminated by a controller of the charged particle detector.
130. The system of clause 118, wherein proximity of the first sensing element to a boundary of the grouping of sensing elements comprises the first sensing element being adjacent to the boundary of the grouping of sensing elements.
131. The system of clause 118, wherein the first sensing element comprises a PIN diode.
132. A method of updating a grouping of sensing elements in a charged particle detector, the method comprising:
   irradiating a sample to produce a secondary beam spot on the charged particle detector, the secondary beam spot overlapping the grouping of sensing elements;
   identifying a first sensing element as a candidate for updating a grouping status of the first sensing element;
   identifying a second sensing element as a candidate for updating a grouping status of the second sensing element, the second sensing element being adjacent to the first sensing element;
   initiating a first thresholding operation of the first sensing element by a first threshold circuit, the first threshold circuit being coupled to the first sensing element and to a first switching element of a switching matrix of the charged particle detector; and
   initiating a second thresholding operation of the second sensing element by a second threshold circuit, the second threshold circuit being coupled to the second sensing element and to a second switching element of the switching matrix of the charged particle detector;
   wherein the first thresholding operation comprises comparing a signal level of the first sensing element to a first threshold; and
   the second thresholding operation comprises comparing a signal level of the second sensing element to a second threshold different from the first threshold.
133. The method of clause 132, wherein:
   the first sensing element is a grouped sensing element on an inside of a boundary of the grouping of sensing elements; and
   the second sensing element is an ungrouped sensing element on an outside of the boundary of the grouping of sensing elements.
134. The method of clause 133, further comprising:
   in response to the signal level of the first sensing element being below the first threshold in the first thresholding operation, updating the grouping status of the first sensing element by opening the first switching element to remove the first sensing element from the grouping of sensing elements.
135. The method of clause 134, further comprising:
   in response to removing the first sensing element from the grouping of sensing elements, terminating the second thresholding operation of the second threshold circuit.
136. The method of clause 134, further comprising:
   in response to removing the first sensing element from the grouping of sensing elements, initiating a third thresholding operation of the first sensing element by the first threshold circuit;
   wherein the third thresholding operation comprises comparing a signal level of the first sensing element to the second threshold.
137. The method of clause 133, further comprising:
   in response to the signal level of the second sensing element exceeding the second threshold in the second thresholding operation, updating the grouping status of the second sensing element by closing the second switching element to add the second sensing element to the grouping of sensing elements.
138. The method of clause 137, further comprising:
   in response to adding the second sensing element to the grouping of sensing elements, terminating the first thresholding operation of the first threshold circuit.
139. The method of clause 137, further comprising:
   in response to adding the second sensing element to the grouping of sensing elements, initiating a third thresholding operation of the second sensing element by the second threshold circuit;
   wherein the third thresholding operation comprises comparing a signal level of the second sensing element to the first threshold.
140. The method of clause 137, further comprising:
   in response to adding the second sensing element to the grouping of sensing elements, initiating a third thresholding operation of a third sensing element by a third threshold circuit;
   wherein the third thresholding operation comprises comparing a signal level of the third sensing element to the second threshold.
141. The method of clause 132, wherein the second threshold is higher than the first threshold.
142. A non-transitory computer-readable medium that stores a set of instructions that is executable by at least one processor of an apparatus to cause the apparatus to perform a method of updating a grouping of sensing elements based on a beam spot being exposed on a charged particle detector, the method comprising:
   identifying a first sensing element as a candidate for updating a grouping status of the first sensing element;
   identifying a second sensing element as a candidate for updating a grouping status of the second sensing element, the second sensing element being adjacent to the first sensing element;
   initiating a first thresholding operation of the first sensing element by a first threshold circuit, the first threshold circuit being coupled to the first sensing element and to a first switching element of a switching matrix of the charged particle detector;
   initiating a second thresholding operation of the second sensing element by a second threshold circuit,
   the second threshold circuit being coupled to the second sensing element and to a second switching element of the switching matrix of the charged particle detector; wherein the first thresholding operation comprises comparing a signal level of the first sensing element to a first threshold; and
   the second thresholding operation comprises comparing a signal level of the second sensing element to a second threshold different from the first threshold.
143. The non-transitory computer-readable medium of clause 142, wherein:
   the first sensing element is a grouped sensing element on an inside of a boundary of the grouping of sensing elements; and
   the second sensing element is an ungrouped sensing element on an outside of the boundary of the grouping of sensing elements.
144. The non-transitory computer-readable medium of clause 143, wherein the set of instructions that is executable by at least one processor of the apparatus being configured to cause the apparatus to further perform:
   in response to the signal level of the first sensing element being below the first threshold in the first thresholding operation, updating the grouping status of the first sensing element by opening the first switching element to remove the first sensing element from the grouping of sensing elements.
145. The non-transitory computer-readable medium of clause 144, wherein the set of instructions that is executable by at least one processor of the apparatus being configured to cause the apparatus to further perform:
   in response to removing the first sensing element from the grouping of sensing elements, terminating the second thresholding operation of the second threshold circuit.
146. The non-transitory computer-readable medium of clause 144, wherein the set of instructions that is executable by at least one processor of the apparatus being configured to cause the apparatus to further perform:
   in response to removing the first sensing element from the grouping of sensing elements, initiating a third thresholding operation of the first sensing element by the first threshold circuit;
   wherein the third thresholding operation comprises comparing a signal level of the first sensing element to the second threshold.
147. The non-transitory computer-readable medium of clause 143, wherein the set of instructions that is executable by at least one processor of the apparatus being configured to cause the apparatus to further perform:
   in response to the signal level of the second sensing element exceeding the second threshold in the second thresholding operation, updating the grouping status of the second sensing element by closing the second switching element to add the second sensing element to the grouping of sensing elements.
148. The non-transitory computer-readable medium of clause 147, wherein the set of instructions that is executable by at least one processor of the apparatus being configured to cause the apparatus to further perform:
   in response to adding the second sensing element to the grouping of sensing elements, terminating the first thresholding operation of the first threshold circuit.
149. The non-transitory computer-readable medium of clause 147, wherein the set of instructions that is executable by at least one processor of the apparatus being configured to cause the apparatus to further perform:
   in response to adding the second sensing element to the grouping of sensing elements, initiating a third thresholding operation of the second sensing element by the second threshold circuit;
   wherein the third thresholding operation comprises comparing a signal level of the second sensing element to the first threshold.
150. The non-transitory computer-readable medium of clause 147, wherein the set of instructions that is executable by at least one processor of the apparatus being configured to cause the apparatus to further perform:
   in response to adding the second sensing element to the grouping of sensing elements, initiating a third thresholding operation of a third sensing element by a third threshold circuit;
   wherein the third thresholding operation comprises comparing a signal level of the third sensing element to the second threshold.
151. The non-transitory computer-readable medium of clause 142, wherein the second threshold is higher than the first threshold.
152. A system comprising:
   a charged particle detector comprising a plurality of sensing elements and configured to be exposed to a beam spot that overlaps on a group of sensing elements;
   a controller having circuitry configured to update a grouping of sensing elements in a charged particle detector by:
   identifying a first sensing element as a candidate for updating a grouping status of the first sensing element;
   identifying a second sensing element as a candidate for updating a grouping status of the second sensing element, the second sensing element being adjacent to the first sensing element;
   initiating a first thresholding operation of the first sensing element by a first threshold circuit, the first threshold circuit being coupled to the first sensing element and to a first switching element of a switching matrix of the charged particle detector;
   initiating a second thresholding operation of the second sensing element by a second threshold circuit,
   the second threshold circuit being coupled to the second sensing element and to a second switching element of the switching matrix of the charged particle detector; wherein the first thresholding operation comprises comparing a signal level of the first sensing element to a first threshold; and
   the second thresholding operation comprises comparing a signal level of the second sensing element to a second threshold different from the first threshold.
153. The system of clause 152, wherein:
   the first sensing element is a grouped sensing element on an inside of a boundary of the grouping of sensing elements; and
   the second sensing element is an ungrouped sensing element on an outside of the boundary of the grouping of sensing elements.
154. The system of clause 153, the controller having circuitry configured to further perform:
   in response to the signal level of the first sensing element being below the first threshold in the first thresholding operation, updating the grouping status of the first sensing element by opening the first switching element to remove the first sensing element from the grouping of sensing elements.
155. The system of clause 154, the controller having circuitry configured to further perform:
   in response to removing the first sensing element from the grouping of sensing elements, terminating the second thresholding operation of the second threshold circuit.
156. The system of clause 154, the controller having circuitry configured to further perform:
   in response to removing the first sensing element from the grouping of sensing elements, initiating a third thresholding operation of the first sensing element by the first threshold circuit;
   wherein the third thresholding operation comprises comparing a signal level of the first sensing element to the second threshold.
157. The system of clause 153, the controller having circuitry configured to further perform:
   in response to the signal level of the second sensing element exceeding the second threshold in the second thresholding operation, updating the grouping status of the second sensing element by closing the second switching element to add the second sensing element to the grouping of sensing elements.
158. The system of clause 157, the controller having circuitry configured to further perform:
   in response to adding the second sensing element to the grouping of sensing elements, terminating the first thresholding operation of the first threshold circuit.
159. The system of clause 157, the controller having circuitry configured to further perform:
   in response to adding the second sensing element to the grouping of sensing elements, initiating a third thresholding operation of the second sensing element by the second threshold circuit;
   wherein the third thresholding operation comprises comparing a signal level of the second sensing element to the first threshold.
160. The system of clause 157, the controller having circuitry configured to further perform:
   in response to adding the second sensing element to the grouping of sensing elements, initiating a third thresholding operation of a third sensing element by a third threshold circuit;
   wherein the third thresholding operation comprises comparing a signal level of the third sensing element to the second threshold.
161. The system of clause 152, wherein the second threshold is higher than the first threshold.
162. A charged particle detector comprising:
   a substrate;
   a plurality of switching elements formed on the substrate and configured to form a switching matrix,
   the switching matrix having a plurality of inputs, each of the inputs being configured to connect to a different one of a plurality of sensing elements, each of the sensing elements being configured to generate a signal in response to a charged particle impacting the sensing element, the switching matrix being configured to combine a grouping of signals generated from a grouping of sensing elements, the grouping of sensing elements being associated with a charged particle beam spot formed on the charged particle detector; and
   a plurality of threshold circuits, each of the threshold circuits being coupled to a different one of the plurality of sensing elements,
   wherein a first threshold circuit of the plurality of threshold circuits is coupled to a first sensing element of the plurality of sensing elements and is configured to actuate a first switching element of the switch matrix based on a comparison of a signal level of the first sensing element to a first threshold;
   wherein a second threshold circuit of the plurality of threshold circuits is coupled to a second sensing element of the plurality of sensing elements and is configured to actuate a second switching element of the switch matrix based on a comparison of a signal level of the second sensing element to a second threshold;
   wherein the first sensing element is adjacent to the second sensing element; and wherein the first threshold is different from the second threshold.
163. The charged particle detector of clause 162, wherein the first threshold circuit is configured to close the first switching element, to cause the first switching element to conduct current, in response to the signal level of the first sensing element exceeding the first threshold.
164. The charged particle detector of clause 163, wherein the first sensing element is added to the grouping of sensing elements by the closing of the first switching element by the first threshold circuit to cause the signal from the first sensing element to be combined with the grouping of signals generated from the grouping of sensing elements.
165. The charged particle detector of clause 164, wherein
   the second sensing element is in a grouped status with the grouping of sensing elements; and
   the second sensing element is coupled to the first sensing element by the first switching element.
166. The charged particle detector of clause 164, wherein
   in response to the first sensing element being added to the grouping of sensing elements, the first threshold circuit is configured to actuate the first switching element of the switch matrix based on a comparison of the signal level of the first sensing element to the second threshold.
167. The charged particle detector of clause 162, wherein the second threshold circuit is configured to open the second switching element, to prevent the second switching element from conducting current,
   in response to the signal level of the second sensing element being below the second threshold.
168. The charged particle detector of clause 167, wherein the second sensing element is removed from the grouping of sensing elements by the opening of the second switching element by the second threshold circuit to prevent the signal from the second sensing element from being combined with the grouping of signals generated from the grouping of sensing elements.
169. The charged particle detector of clause 168, wherein
   in response to the second sensing element being removed from the grouping of sensing elements, the first threshold circuit is configured to terminate the comparison of the signal level of the first sensing element to the first threshold.
170. The charged particle detector of clause 168, wherein
   in response to the second sensing element being removed from the grouping of sensing elements, the second threshold circuit is configured to actuate the second switching element of the switch matrix based on a comparison of the signal level of the second sensing element to the first threshold.
171. The charged particle detector of clause 162, wherein the first threshold circuit is configured to initiate the comparison of the signal level of the first sensing element to the first threshold in response to the first sensing element being adjacent to an exterior boundary of the grouping of sensing elements.
172. The charged particle detector of clause 12, wherein the second threshold circuit is configured to initiate the comparison of the signal level of the second sensing element to the second threshold in response to the second sensing element being adjacent to an interior boundary of the grouping of sensing elements.
173. The charged particle detector of clause 1, wherein the substrate includes the plurality of transistors.

It will be appreciated that the embodiments of the present disclosure are not limited to the exact construction that has been described above and illustrated in the accompanying drawings and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A charged particle detector comprising:
a substrate;
a plurality of switching elements formed on the substrate and configured to form a switching matrix, the switching matrix having a plurality of inputs, each of the inputs being configured to connect to a different one of a plurality of sensing elements, each of the sensing elements being configured to generate a signal in response to a charged particle impacting the sensing element, the switching matrix being configured to combine a grouping of signals generated from a grouping of sensing elements, the grouping of sensing elements being associated with a charged particle beam spot formed on the charged particle detector; and
a plurality of threshold circuits, each of the threshold circuits being coupled to a different one of the plurality of sensing elements,
wherein a first threshold circuit of the plurality of threshold circuits is coupled to a first sensing element of the plurality of sensing elements and is configured to actuate a first switching element of the switching matrix based on a comparison of a signal level of the first sensing element to a threshold;
wherein the first sensing element is configured to be identified as a candidate for one of being added to the grouping of sensing elements and being removed from the grouping of sensing elements based on proximity of the first sensing element to a boundary of the grouping of sensing elements; and
wherein the first threshold circuit is configured to initiate the comparison in response to the first sensing element being identified as the candidate.

2. The charged particle detector of claim 1, wherein the first threshold circuit is configured to close the first switching element, to cause the first switching element to conduct current, in response to the signal level of the first sensing element exceeding the threshold.

3. The charged particle detector of claim 2, wherein the first sensing element is added to the grouping of sensing elements by the closing of the first switching element by the first threshold circuit to cause the signal from the first sensing element to be combined with the grouping of signals generated from the grouping of sensing elements.

4. The charged particle detector of claim 3,
wherein the threshold is a first threshold, and
the first threshold circuit is configured to open the first switching element, to prevent the first switching element from conducting current, in response to the signal level of the first sensing element falling below a second threshold, wherein the second threshold is lower than the first threshold.

5. The charged particle detector of claim 4, wherein the first sensing element is removed from the grouping of sensing elements by the opening of the first switching element by the first threshold circuit to prevent the signal from the first sensing element from being combined with the grouping of signals generated from the grouping of sensing elements.

6. The charged particle detector of claim 1, wherein the first threshold circuit is configured to open the first switching element, to prevent the first switching element from conducting current, in response to the signal level of the first sensing element falling below the threshold.

7. The charged particle detector of claim 6, wherein the first sensing element is removed from the grouping of sensing elements by the opening of the first switching element by the first threshold circuit to prevent the signal from the first sensing element from being combined with the grouping of signals generated from the grouping of sensing elements.

8. The charged particle detector of claim 7, wherein the threshold is a second threshold, and
the first threshold circuit is configured to close the first switching element, to cause the first switching element to conduct current, in response to the signal level of the first sensing element exceeding a first threshold, wherein the first threshold is higher than the second threshold.

9. The charged particle detector of claim 8, wherein the first sensing element is added to the grouping of sensing elements by the closing of the first switching element by the first threshold circuit to cause the signal from the first sensing element to be combined with the grouping of signals generated from the grouping of sensing elements.

10. The charged particle detector of claim 1, further comprising:
a second sensing element adjacent to the first sensing element;
wherein proximity of the first sensing element to a boundary of the grouping of sensing elements is determined based on the first sensing element having a different grouping status from the second sensing element.

11. The charged particle detector of claim 10, wherein:
the first sensing element is in a grouped status with the grouping of sensing elements;
the second sensing element is in an ungrouped status from the grouping of sensing elements;
the first sensing element is a candidate for being removed from the grouping of sensing elements; and
the second sensing element is a candidate for being added to the grouping of sensing elements.

12. The charged particle detector of claim 11, wherein the first threshold circuit is configured to remove the first sensing element from the grouping of sensing elements by opening the first switching element in response to the first signal level being below the threshold.

13. The charged particle detector of claim 10, wherein:
the first sensing element is in an ungrouped status from the grouping of sensing elements;
the second sensing element is in a grouped status with the grouping of sensing elements;
the first sensing element is a candidate for being added to the grouping of sensing elements; and
the second sensing element is a candidate for being removed from the grouping of sensing elements

14. The charged particle detector of claim 13, wherein the first threshold circuit is configured to add the first sensing element to the grouping of sensing elements by closing the first switching element in response to the first signal level exceeding the threshold.

15. A non-transitory computer-readable medium that stores a set of instructions that is executable by at least one processor of an apparatus to cause the apparatus to perform a method of reducing noise of an electron detector of a multi-beam SEM, the method comprising:
receiving, by sensing elements of an electron detector, electrons from multiple secondary electron beams emitted by a sample in response to a plurality of primary beams of the multi-beam SEM interacting with the sample, each of the secondary beams being associated with a different one of the plurality of primary beams;
based on the received electrons, coupling a first grouping of the sensing elements of the electron detector corresponding to a first beam spot of one of the secondary electron beams; and
coupling a first sensing element to the first grouping in response to a first detected charge at the first sensing element exceeding a first threshold, wherein coupling the first sensing element to the first grouping enables charge to be passed from the first sensing element to a signal readout path of the first grouping; or
decoupling a second sensing element from the first grouping in response to a second detected charge at the second sensing element falling below a second threshold, wherein decoupling the second sensing element from the first grouping prevents charge from being passed from the second sensing element to the signal readout path of the first grouping.

16. The non-transitory computer-readable medium of claim 15, wherein the first and second thresholds are equal.

17. The non-transitory computer-readable medium of claim 15, wherein the first threshold is greater than the second threshold.

18. The non-transitory computer-readable medium of claim 17, wherein the set of instructions that is executable by at least one processor of an apparatus being configured to cause the apparatus to further perform:
continuing to enable the detected charge to be passed to the signal readout path in response to:
the first detected charge exceeding the first threshold and being passed to the signal readout path; and
the first detected charge subsequently falling to an intermediate range below the first threshold and above the second threshold.

19. The non-transitory computer-readable medium of claim 17, wherein the set of instructions that is executable by at least one processor of an apparatus being configured to cause the apparatus to further perform:
continuing to prevent the detected charge from being passed to a switching matrix in response to:
the second detected charge not exceeding the second threshold and being prevented from being passed to the signal readout path; and
the second detected charge subsequently rising to an intermediate range below the first threshold and above the second threshold.

20. A detector comprising:
a substrate;
a plurality of switching elements formed on the substrate and configured to form a switching matrix, the switching matrix having a plurality of inputs, each of the inputs being configured to connect to a different one of a plurality of sensing elements, each of the sensing elements being configured to generate a signal in response to an arrival of energy at the sensing element, the switching matrix being configured to combine a grouping of signals generated from a grouping of sensing elements, the grouping of sensing elements being associated with a beam spot formed on the detector; and
a plurality of transistors forming a plurality of threshold circuits, each of the threshold circuits being coupled to a different one of the plurality of sensing elements,
wherein a first threshold circuit of the plurality of threshold circuits is coupled to a first sensing element of the plurality of sensing elements and is configured to actuate a first switching element of the switch matrix based on a comparison of a signal level of the first sensing element to a threshold.
